(19) United States
(12) Patent Application Publication
(10) Pub. No.: US 2025/0380484 A1
(43) Pub. Date: Dec. 11, 2025

(54) USING A DIPOLE LAYER TO DOPE A GATE DIELECTRIC OF A GATE-ALL-AROUND DEVICE

(71) Applicant: Taiwan Semiconductor Manufacturing Company, Ltd., Hsin-Chu (TW)

(72) Inventors: Ming-Ho Lin, Taipei City (TW); Chun-Yen Peng, Hsinchu (TW); Cheng-Hao Hou, Hsinchu (TW); Tsung-Da Lin, Hsinchu (TW); Chi On Chui, Hsinchu City (TW)

(21) Appl. No.: 18/818,468

(22) Filed: Aug. 28, 2024

Related U.S. Application Data
(60) Provisional application No. 63/656,671, filed on Jun. 6, 2024.

(51) Int. Cl. H01L 29/423; H01L 21/28; H01L 21/8238; H01L 27/092; H01L 29/06; H01L 29/51; H01L 29/66; H01L 29/775; H01L 29/786

(52) U.S. Cl. CPC H10D 64/514; H01L 21/28185; H10D 64/693; H10D 84/0181; H10D 84/038; H10D 84/856; H10D 30/014; H10D 30/43; H10D 30/6735; H10D 30/6757; H10D 62/121

(57) ABSTRACT

A stack of semiconductor layers is formed. The semiconductor layers are spaced apart from one another in a vertical direction by a plurality of gaps in a cross-sectional side view. A plurality of gate dielectric layers is formed over the semiconductor layers. Each of the gate dielectric layers circumferentially surrounds a respective one of the semiconductor layers, and the gate dielectric layers are still spaced apart from one another in the vertical direction by the gaps in the cross-sectional side view. A dipole layer is formed that circumferentially surrounds each of the gate dielectric layers in the cross-sectional side view. The dipole layer contains dopants. The gaps are filled by different portions of the dipole layer in the cross-sectional side view. One or more annealing processes is performed to drive dopants of the dipole layer into the gate dielectric layers. The dipole layer is then removed.

### PRIORITY

This application claims the priority of U.S. Provisional Application Ser. No. 63/656,671, filed Jun. 6, 2024, entitled “DIPOLE CO-INTEGRATED PATTERNING LOOPS ON SQUARE-GATE-ALL-AROUND DEVICE,” the entire disclosure of which is incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with conventional IC manufacturing processes. As GAA devices continue to scale, challenges have arisen. For example, it may be more difficult to tune a threshold voltage by configuring a thickness of a dipole layer alone. As a result, device performance may be unsatisfactory. Therefore, although existing IC structures and fabrication techniques have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flowchart of a method for fabricating a semiconductor structure according to various aspects of the present disclosure.

FIG. 2 is a top view of a semiconductor structure according to some embodiments of the present disclosure.

FIGS. 3, 4A, 5A, 6A, 7A, 8A, 9A, 10, 11A, and 12A are cross-sectional side views of a semiconductor structure along the line A-A′ in FIG. 2, at various fabrication stages, according to some embodiments of the present disclosure.

FIGS. 4B, 5B, 6B, 7B, 8B, 9B, 11B, and 12B are enlarged views of a portion of the semiconductor structure in FIGS. 4A-9A and 11A-12A, respectively, according to some embodiments of the present disclosure.

FIG. 11C is a cross-sectional side view of the semiconductor structure in FIG. 11A and along the line B-B′ as in FIG. 2, according to some embodiments of the present disclosure.

FIGS. 13A and 13B are cross-sectional side views of a portion of a semiconductor structure according to some embodiments of the present disclosure.

FIGS. 14A and 14B are cross-sectional side views of a portion of a semiconductor structure according to some embodiments of the present disclosure.

FIGS. 15-28 are cross-sectional side views of a portion of a semiconductor structure at various stages of fabrication according to some embodiments of the present disclosure.

FIG. 29 is a circuit diagram of a memory cell according to some embodiments of the present disclosure.

FIG. 30 is a block diagram of a semiconductor fabrication facility according to some embodiments of the present disclosure.

### DETAILED DESCRIPTION

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

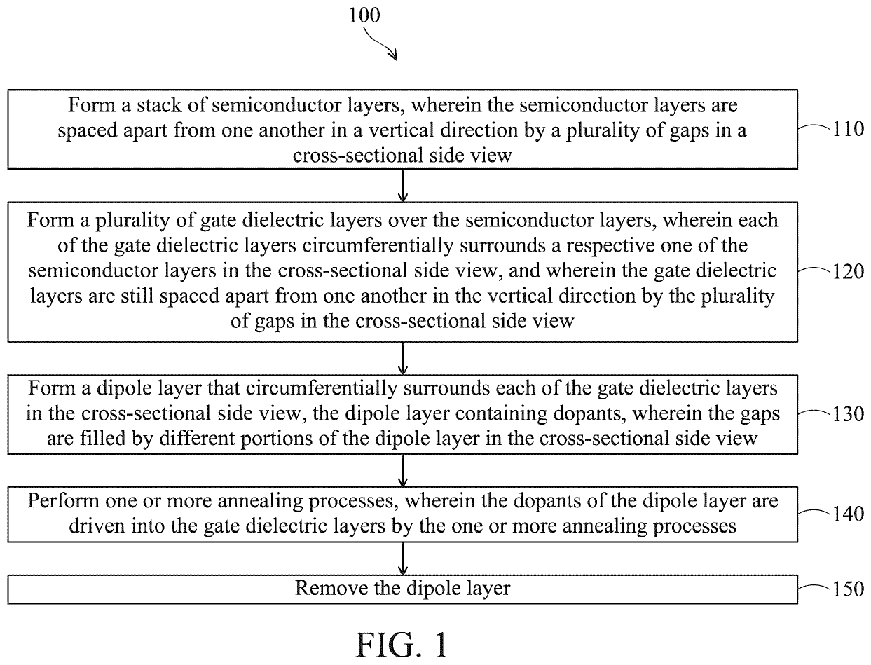

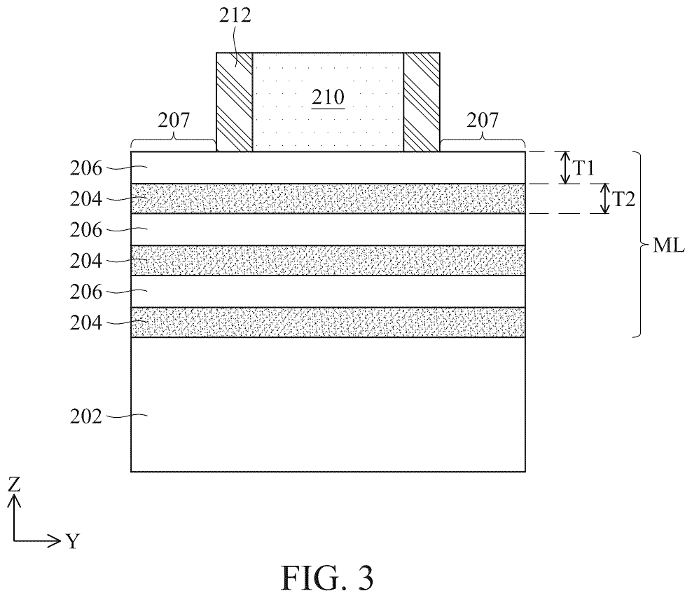

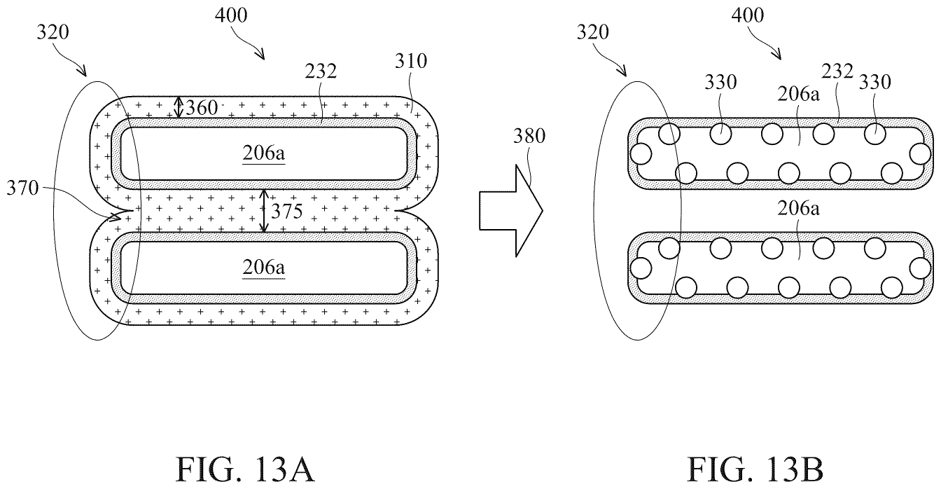

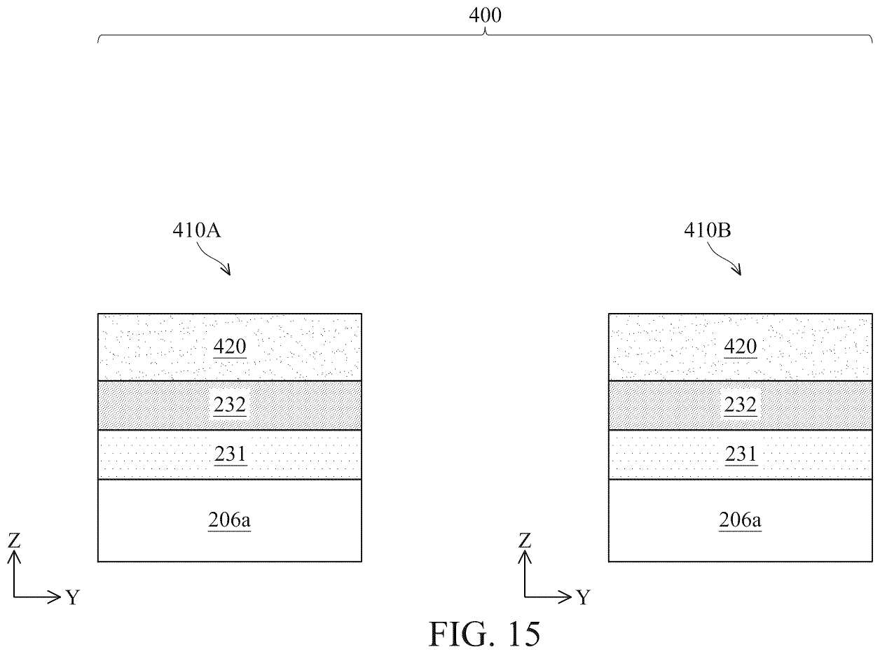

Multi-gate devices (e.g. gate-all-around (GAA) devices) have been introduced in an effort to improve gate control by increasing gate-channel coupling, reduce OFF-state current, and reduce short-channel effects (SCEs). GAA devices can be aggressively scaled down while maintaining gate control and mitigating SCEs. However, GAA devices may still face certain challenges. For example, dipole layers can be formed on a gate dielectric layer, where dipole dopants are driven into the gate dielectric to tune a threshold voltage of a GAA device. However, as GAA devices continue to get scaled down, the dipole dopant distribution within the gate dielectric layer may become non-uniform, which may be referred to as a loading effect. Such a loading effect may affect the threshold voltage tuning and could lead to unsatisfactory device performance. The present disclosure pertains to methods performed as a part of the GAA fabrication to address these issues discussed above, such that the resulting device can achieve better dipole dopant distribution within the gate dielectric layer, as discussed below in more detail. Specifically, the discussions associated with FIG. 1 describe a method of fabricating a semiconductor structure according to embodiments of the present disclosure. The discussions associated with FIGS. 3, 4A-9A, 4B-9B, 10, 11A-12A, 11B-12B, and 11C describe a process to fabricate a GAA device with square-like channels, which make them more susceptible to dipole loading effect issues. The discussions associated with FIGS. 13A-13D describe a solution to overcoming a dipole loading effect. The discussions associated with FIGS. 15-28 describe various embodiments of detailed fabrication process flows for implementing a dipole layer in a manner to minimize the dipole loading effect.

Referring now to FIG. 1, a flow chart of an example method 100 for fabricating an embodiment of a semiconductor device is illustrated. In some embodiments, the semiconductor device is a GAA device where its gate structure, or portions thereof, are formed around all-sides of a channel region (e.g. surrounding a portion of a channel region). In some instances, a GAA device may also be referred to as a quad-gate device where the channel region has four sides and the gate structure is formed on all four sides. The channel region of a GAA device may include one or more semiconductor layers, each of which may be in one of many different shapes, such as wire (or nanowire), sheet (or nanosheet), bar (or nano-bar), and/or other suitable shapes. In embodiments, the channel region of a GAA device may have multiple horizontal semiconductor layers (such as nanowires, nanosheets, or nano-bars) (hereinafter collectively referred to as “nanochannels”) vertically spaced, making the GAA device a stacked horizontal GAA device. The GAA devices presented herein may be a complementary metal-oxide-semiconductor (CMOS) GAA device, a p-type metal-oxide-semiconductor (pMOS) GAA device, or an n-type metal-oxide-semiconductor (nMOS) GAA device. Further, the GAA devices may have one or more channel regions associated with a single, contiguous gate structure, or multiple gate structures. One of ordinary skill may recognize other examples of semiconductor devices that may benefit from aspects of the present disclosure. For example, other types of metal-oxide semiconductor field effect transistors (MOSFETs), such as planar MOSFETs, FinFETs, other multi-gate FETs may benefit from the present disclosure. The GAA devices and methods of manufacture that are proposed in the present disclosure exhibit desirable properties, examples being: reduced doping diffusion, reduced built-in stress, reduced device degradation, improved silicon performance, higher current drive, reduced short-channel effects (SCEs), and decreased capacitance between adjacent conductive regions, such as between a source/drain region and adjacent SiGe residue.

The method 100 includes a step 110, in which a stack of semiconductor layers is formed. The semiconductor layers are spaced apart from one another in a vertical direction by a plurality of gaps in a cross-sectional side view.

The method 100 includes a step 120, in which a plurality of gate dielectric layers is formed over the semiconductor layers. Each of the gate dielectric layers circumferentially surrounds a respective one of the semiconductor layers in the cross-sectional side view. The gate dielectric layers are still spaced apart from one another in the vertical direction by the plurality of gaps in the cross-sectional side view.

The method 100 includes a step 130, in which a dipole layer is formed that circumferentially surrounds each of the gate dielectric layers in the cross-sectional side view, the dipole layer containing dopants. The gaps are filled by different portions of the dipole layer in the cross-sectional side view.

The method 100 includes a step 140, in which one or more annealing processes are performed. The dopants of the dipole layer are driven into the gate dielectric layers by the one or more annealing processes.

The method 100 includes a step 150, in which the dipole layer is removed.

In some embodiments, the semiconductor layers are first semiconductor layers, and the method 100 may include the following steps before the plurality of the gate dielectric layers is formed: forming a plurality of second semiconductor layers that interleave with the first semiconductor layers, wherein the first semiconductor layers and the second semiconductor layers have different material compositions; replacing the second semiconductor layers with a plurality of sacrificial dielectric layers; laterally etching the sacrificial dielectric layers; forming inner spacers on side surfaces of the laterally etched sacrificial dielectric layers; and replacing the laterally etched sacrificial dielectric layers with a gate structure, wherein the gate structure includes the plurality of the gate dielectric layers.

In some embodiments, the forming the dipole layer comprises depositing a plurality of dipole layer segments on the plurality of gate dielectric layers, respectively, and the deposited plurality of dipole layer segments are thick enough to merge into one another vertically to form the dipole layer.

In some embodiments, the forming the stack of semiconductor layers comprises a first stack of the semiconductor layers and a second stack of the semiconductor layers, and the forming the plurality of the gate dielectric layers comprises forming a plurality of first gate dielectric layers over the first stack of semiconductor layers and forming a plurality of second gate dielectric layers over the second stack of semiconductor layers. The method 100 may further include the following steps: forming first portions of a mask layer over the first gate dielectric layers and forming second portions of the mask layer over the second gate dielectric layers; patterning the mask layer at least in part by removing the first portions of the mask layer, while the second portions of the mask layer remain substantially intact after the first portions of the mask layer have been removed. The forming the dipole layer may comprise forming first portions of the dipole layer on the first gate dielectric layers and forming second portions of the dipole layer on the second portions of the mask layer. In some embodiments, the one or more annealing processes drive dopants of the first portions of the dipole layer into the first gate dielectric layers; and the second portions of the mask layer prevent dopants of the second portions of the dipole layer from being driven into the second gate dielectric layers. In some embodiments, the removing the dipole layer comprises removing the first portions of the dipole layer and the second portions of the dipole layer; and the first gate dielectric layers are each thinner than each of the second gate dielectric layers after the removing of the dipole layer. In some embodiments, the first portions of the mask layer are removed at least in part using an etching process with a nitrogen-based etchant or an oxygen-based etchant; and the etching process causes the nitrogen-based etchant or the oxygen-based etchant to penetrate into the first gate dielectric layers but not into the second gate dielectric layers.

In some embodiments, the forming the stack of semiconductor layers comprises a first stack of the semiconductor layers and a second stack of the semiconductor layers; the forming the plurality of the gate dielectric layers comprises forming a plurality of first gate dielectric layers over the first stack of semiconductor layers and forming a plurality of second gate dielectric layers over the second stack of semiconductor layers. The method may further include the following steps: forming first portions of a mask layer over the first portions of the dipole layer and forming second portions of the mask layer over the second portions of the dipole layer; and patterning the mask layer and the dipole layer at least in part by removing the second portions of the mask layer and the second portions of the dipole layer, while the first portions of the mask layer and the first portions of the dipole layer remain substantially intact after the second portions of the mask layer and the second portions of the dipole layer have been removed. In some embodiments, the one or more annealing processes drive dopants of the first portions of the dipole layer into the first gate dielectric layers, and wherein the method further comprises removing the first portions of the mask layer before the dopants of the first portions of the dipole layer have been driven into the first gate dielectric layers. In some embodiments, the second portions of the mask layer are removed at least in part using an etching process with a nitrogen-based etchant or an oxygen-based etchant; and the etching process causes the nitrogen-based etchant or the oxygen-based etchant to penetrate into the second gate dielectric layers but not into the first gate dielectric layers.

In some embodiments, the performing the one or more annealing processes comprises: performing a first annealing process with a process temperature in a range between about 500 degrees C. and about 800 degrees C.; and performing a second annealing process with a process temperature in a range between about 800 degrees C. and about 1200 degrees C.

It is understood that the method 100 may include steps that are performed before, during, and/or after the steps 110-150. For example, the method 100 may include a step of forming a metal gate electrode over the gate dielectric layers, as well as forming conductive vias or contacts. For reasons of simplicity, these steps are not specifically discussed in detail herein.

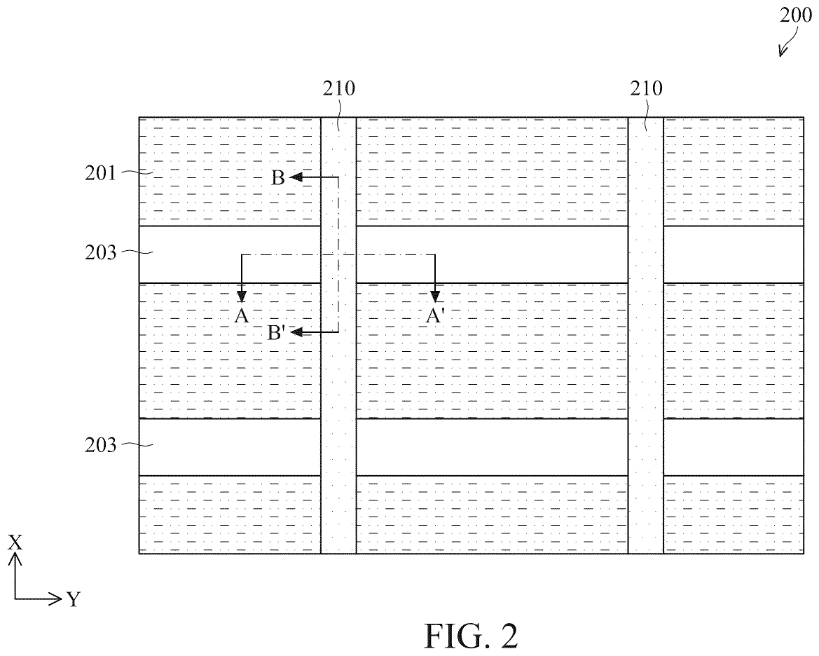

Referring to FIGS. 2 and 3, a semiconductor structure 200 fabricated according to the various aspects of the present disclosure includes semiconductor substrate 202 and a plurality of fins 203 protruding from the semiconductor substrate 202. The fins 203 and separated by isolation features 201 and one or more dummy gate stacks 210 disposed over the fins 203.

In some embodiments, the semiconductor substrate 202 includes a semiconductor material, such as bulk silicon (Si). Alternatively, or additionally, another elementary semiconductor, such as germanium (Ge) in a crystalline structure, may also be included in the semiconductor substrate 202. The semiconductor substrate 202 may also include a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb), or combinations thereof. The semiconductor substrate 202 may also include a semiconductor-on-insulator substrate, such as Si-on-insulator (SOI), SiGe-on-insulator (SGOI), Ge-on-insulator (GOI) substrates.

Portions of the semiconductor substrate 202 may be doped and referred to as doped portions. The doped portions may be doped with p-type dopants, such as boron (B) or boron fluoride (BF3), or doped with n-type dopants, such as phosphorus (P) or arsenic (As). The doped portions may also be doped with combinations of p-type and n-type dopants (e.g. to form a p-type well and an adjacent n-type well). The doped portions may be formed directly on the semiconductor substrate 202, in a p-well structure, in an n-well structure, in a dual-well structure, or using a raised structure.

In some embodiments, semiconductor layers 204 and 206 (collectively referred to as a “multi-layer stack” or “ML”) are formed over the semiconductor substrate 202 in an interleaving or alternating fashion, extending vertically (e.g. along the Z-direction in FIG. 3) from the semiconductor substrate 202. For example, a semiconductor layer 204 is disposed over the semiconductor substrate 202, a semiconductor layer 206 is disposed over the semiconductor layer 204, another semiconductor layer 204 is disposed over the semiconductor layer 206, so on and so forth. In the depicted embodiments, there are three layers of semiconductor layers 206 and three layers of semiconductor layers 204 alternating between each other. However, there may be any appropriate number of layers in the ML. For example, there may be 2 to 10 layers of semiconductor layers 206, alternating with 2 to 10 layers of semiconductor layers 204 in the ML. The material compositions of the semiconductor layers 206 and the semiconductor layers 204 are configured such that they have an etching selectivity in a subsequent etching process. For example, in some embodiments, the semiconductor layers 204 contain silicon germanium (SiGe), while the semiconductor layers 206 contain silicon (Si). In some other embodiments, the semiconductor layers 206 contain SiGe, while the semiconductor layers 204 contain Si. In the depicted embodiment, each of the semiconductor layers 206 has a substantially same thickness (e.g., less than 5% difference between two semiconductor layers 206), depicted in FIG. 3 as thickness T1, while each of the semiconductor layers 204 has a substantially same thickness (e.g., less than 5% difference between two semiconductor layers 204), depicted in FIG. 3 as thickness T2. T1 and T2 are about 2 nanometers (nm) to about 12 nm.

The stack of semiconductor layers 204 and 206 are then patterned into a plurality of fin structures, for example, into the fins 203 as in FIG. 2. Each of the fins 203 includes a stack of the semiconductor layers 204 and 206 disposed in an alternating manner with respect to one another. The fins 203 each extends lengthwise (e.g. longitudinally) in a horizontal direction (e.g. in the Y-direction) and are separated from each other (e.g. laterally) in a different horizontal direction (e.g. in the X-direction), as shown in FIG. 2. It is understood that the X-direction and the Y-direction are perpendicular to each other, and that the Z-direction is a vertical direction that is orthogonal (or normal) to a plane defined by the X-direction and the Y-direction. The semiconductor substrate 202 may have its top surface aligned in parallel to the X-Y plane.

The fins 203 may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins. The patterning may utilize multiple etching processes which may include a dry etching and/or wet etching. The regions in which the fins are formed will be used to form active devices through subsequent processing and are thus referred to as active regions. For example, each of the fins 203 is formed in an active region. Both of the fins 203 in FIG. 2 protrude out of the semiconductor substrate 202 (e.g., the doped portions).

The semiconductor structure 200 includes isolation features 201, which may include shallow trench isolation (STI) features in some embodiments. The isolation features 201 are formed on the semiconductor substrate 202 and surround the active regions. In some examples, formation of the isolation features 201 includes etching trenches into the semiconductor substrate 202 between the active regions and filling the trenches with one or more dielectric materials such as silicon oxide, silicon nitride, silicon oxynitride, other suitable materials, or combinations thereof. Any appropriate methods, such as a chemical vapor deposition (CVD) process, an atomic layer deposition (ALD) process, a physical vapor deposition (PVD) process, a plasma-enhanced CVD (PECVD) process, a plasma-enhanced ALD (PEALD) process, and/or combinations thereof may be used for depositing the isolation features 201. The isolation features 201 may have a multi-layer structure such as a thermal oxide liner layer over the semiconductor substrate 202 and a filling layer (e.g., silicon nitride or silicon oxide) over the thermal oxide liner layer. Alternatively, the isolation features 201 may be formed using any other isolation formation techniques. Although not depicted, in some embodiments, the fins 203 are located above a top surface of the isolation features 201 (e.g. protrude out of the isolation features 201) and are also located above a top surface of the semiconductor substrate 202.

Referring to FIGS. 2 and 3, the dummy gate stacks 210 are formed over a portion of each of the fins 203, and over the isolation features 201, in between the fins 203. The dummy gate stacks 210 may be configured to extend lengthwise (e.g. longitudinally) in parallel to each other, for example, each along the X-direction, as shown in FIG. 2. In some embodiments, each dummy gate stack 210 wraps around the top surface and side surfaces of each of the fins 203. The dummy gate stack 210 may include polysilicon. In some embodiments, the dummy gate stack 210 also includes one or more mask layers, which are used to pattern the dummy gate electrode layers. The dummy gate stack 210 may undergo a gate replacement process through subsequent processing to form metal gates, such as a high-k metal gate, as discussed in greater detail below. The dummy gate stack 210 may also undergo a second gate replacement process to form a dielectric based gate that electrically isolates the semiconductor structure 200 from neighboring devices. The dummy gate stack 210 may be formed by a procedure including deposition, lithography patterning, and etching processes. The deposition processes may include CVD, ALD, PVD, other suitable methods, and/or combinations thereof.

Referring to FIG. 3, gate spacers 212 are formed on sidewalls of the dummy gate stack 210. The gate spacers 212 include one or more dielectric materials and may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 212 may include a single layer or a multi-layer structure. In some embodiments, each of the gate spacers 212 may have a thickness (e.g. measured in the Y-direction) in a range from about 3 nm to about 10 nm. A thickness within the stated range of values may be needed for device performance, especially for advanced technology nodes. In some embodiments, the gate spacers 212 may be formed by depositing a spacer layer (containing the dielectric material) over the dummy gate stack 210, followed by an anisotropic etching process to remove portions of the spacer layer from the top surfaces of the dummy gate stack 210. After the etching process, portions of the spacer layer on the sidewall surfaces of the dummy gate stack 210 substantially remain and become the gate spacers 212. In some embodiments, the anisotropic etching process is a dry (e.g. plasma) etching process. Additionally, or alternatively, the formation of the gate spacers 212 may also involve chemical oxidation, thermal oxidation, ALD, CVD, and/or other suitable methods. In the active regions, the gate spacers 212 are formed over the top layer of the semiconductor layers 204 and 206. Accordingly, the gate spacers 212 may also be interchangeably referred to as top spacers 212. In some examples, one or more material layers (not shown) may also be formed between the dummy gate stack 210 and the corresponding gate spacers 212. The one or more material layers may include an interfacial layer and/or a high-k dielectric layer (e.g., having a dielectric constant greater than a dielectric constant of silicon oxide, which is about 3.9), as examples.

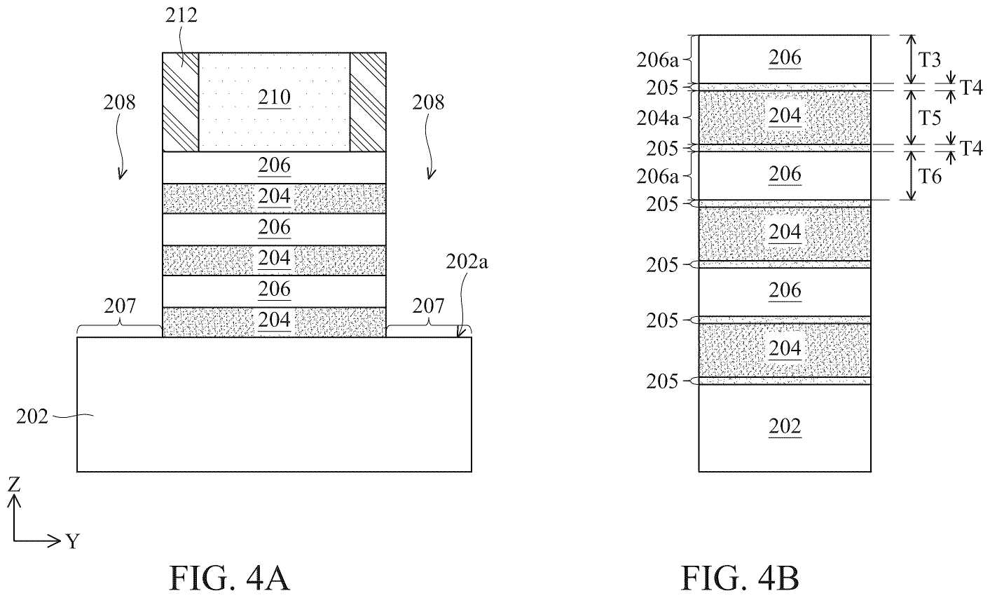

Referring to FIG. 4A, exposed portions of the fins 203 (i.e., source/drain regions 207 of the fins 203 that are not covered by the dummy gate stack 210) are at least partially removed to form source/drain recesses (trenches) 208. Source/drain region(s) may refer to a source or a drain, individually or collectively, depending upon the context. In the depicted embodiment, an etching process completely removes the ML in the source/drain regions 207 of the fins 203, thereby exposing substrate portions of the fins 203 in the source/drain regions 207. The source/drain recesses 208 thus have sidewalls defined by remaining portions of the ML, which are disposed under the dummy gate stack 210, and bottoms defined by the semiconductor substrate 202.

A top surface 202a of the semiconductor substrate 202 is exposed to the source/drain recesses 208. In some embodiments, the etching process removes some, but not all, of the ML, such that the source/drain recesses 208 have bottoms defined by the semiconductor layer 204 or the semiconductor layer 206 in the source/drain regions 207. In some embodiments, the etching process further removes some, but not all, of the substrate portions of the fins 203, such that the source/drain recesses 208 extend below a topmost surface of the semiconductor substrate 202. In other words, the top surface 202a is below a topmost surface of the semiconductor substrate 202. The etching process can include a dry etching process, a wet etching process, other suitable etching process, or combinations thereof. In some embodiments, the etching process is a multi-step etch process. For example, the etching process may alternate etchants to separately and alternately remove the semiconductor layers 204 and the semiconductor layers 206. In some embodiments, parameters of the etching process are configured to selectively etch the ML with minimal (to no) etching of the dummy gate stack 210 and the gate spacers 212 and/or the isolation features 201. In some embodiments, a lithography process, such as those described herein, is performed to form a patterned mask layer that covers the dummy gate stack 210 and the gate spacers 212 and/or the isolation features 201, and the etching process uses the patterned mask layer as an etch mask.

FIG. 4B is an enlarged view of a portion (in the dotted rectangle) of the semiconductor structure 200 in FIG. 4A. In some embodiments, the semiconductor structure 200 further includes intermix layers 205 (also referred to as “transmission layers 205”) having a mixture of materials of the semiconductor layers 204 and the semiconductor layers 206. In some embodiments, the intermix layers 205 are formed from epitaxial growing of the semiconductor layers 204 and 206. The ML can include the intermix layers 205 and core layers 206a and 204a. The core layers 206a and 204a include relatively high concentrations (e.g., greater than 90%) of materials of the semiconductor layers 204 and 206 (e.g., Si or SiGe), respectively. Each of the semiconductor layers 206 can include a core layer 206a and at least a portion of an intermix layer 205. Each of the semiconductor layers 204 can include a core layer 204a and at least a portion of an intermix layer 205.

In some embodiments, the core layer 206a is adjacent to and above the intermix layer 205. In such an intermix layer 205, a concentration of the material of the core layer 206a (e.g., Si) gradually decreases from about 90% to about 10% from top to bottom along the Z-direction, while a concentration of the material of the core layer 204a (e.g., SiGe) gradually increases from about 10% to about 90% from top to bottom along the Z-direction. In such embodiments, an atomic percentage of Ge in the intermix layer 205 gradually increases from about 0.005% to about 20% from top to bottom along the Z-direction. In some other embodiments, the core layer 204a is adjacent to and above the intermix layer 205. In such an intermix layer 205, a concentration of the material of the core layer 206a (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction. In such embodiments, an atomic percentage of Ge in intermix layers 205 gradually decreases from about 20% to about 0.005% from top to bottom along the Z-direction. In some embodiments, the bottommost intermix layer 205 has a concentration of the material of the semiconductor substrate 202 (e.g., Si) gradually increases from about 10% to about 90% from top to bottom along the Z-direction, while a concentration of the material of the core layer 204a (e.g., SiGe) gradually decreases from about 90% to about 10% from top to bottom along the Z-direction.

In the depicted embodiment, the core layer 206a interfacing only one layer of the intermix layers 205 has a thickness T3 ranging from about 2 nm to about 12 nm, the core layer 206a interfacing two layers of the intermix layers 205 has a thickness T6 ranging from about 2 nm to about 12 nm, the core layer 204a interfacing two layers of the intermix layers 205 has a thickness T5 ranging from about 2 nm to about 12 nm, and each of the intermix layers 205 has a substantially same thickness (e.g., less than 5% difference) T4 ranging from about 0.1 nm to about 2 nm. T5 can be equal to T6. In some embodiments, T5 is different from T6.

In some embodiments, each of the semiconductor layers 204 and 206 and the intermix layers 205 have uniform profiles on each X-Y plane. For example, on an X-Y plane across one layer of the intermix layers 205, a concentration of the material of the core layer 204a (e.g., SiGe) is substantially the same. Therefore, an interface between the intermix layer 205 and the adjacent core layer 204a or 206a extends along an X-Y plane, and thicknesses of each core layers 206a or 204a are substantially the same at different locations on an X-Y plane. For example, a thickness of a core layer 206a or 204a close to a sidewall of the core layer 206a or 204a is substantially the same (e.g., less than 5% difference) as a thickness of the core layer 206a or 204a at center (the portion directly under dummy gate stack 210). Similarly, thicknesses of each intermix layers 205 are substantially the same at different locations on an X-Y plane. For example, a thickness of an intermix layer 205 close to a sidewall of the intermix layer 205 is substantially the same (e.g., less than 5% difference) as a thickness of the intermix layer 205 at center (the portion directly under dummy gate stack 210).

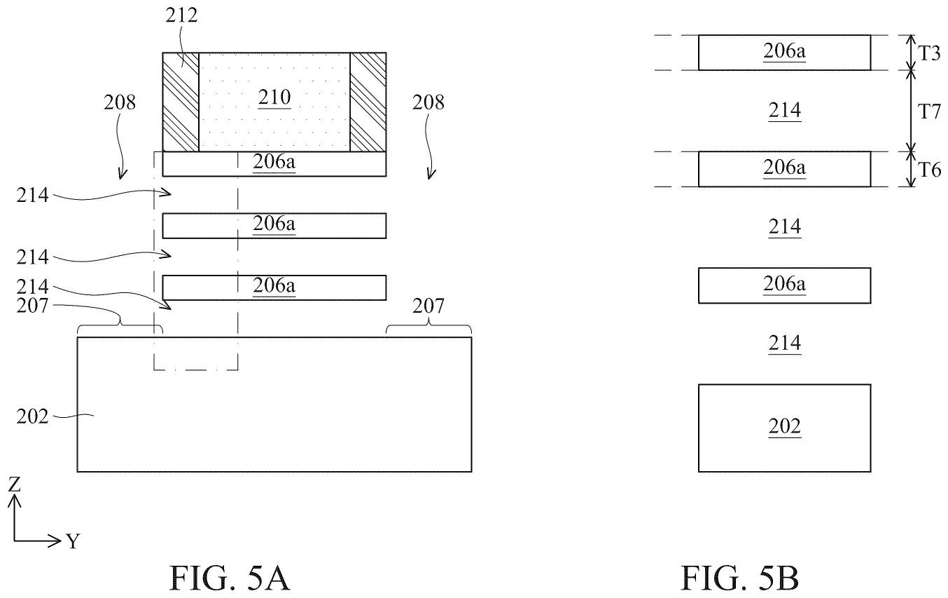

Referring to FIG. 5A, the semiconductor layers 204 (exposed by the source/drain recesses 208) are selectively removed from the ML, thereby forming suspended semiconductor layers 206 and openings 214 in between the vertically (e.g. in the Z-direction) adjacent semiconductor layers 206 (or the semiconductor substrate 202, where applicable). Particularly, the openings 214 are through openings that are overlapped with the core layers 204a and the intermix layers 205, and are spanning between a pair of the source/drain regions 207. FIG. 5B is an enlarged view of a portion (in the dotted rectangle) of the semiconductor structure 200 in FIG. 5A.

In the depicted embodiment, an etching process selectively etches the core layers 204a and the intermix layers 205 with minimal (to no) etching of the core layers 206a and, in some embodiments, minimal (to no) etching of the gate spacers 212. In embodiments, the core layers 206a remain unetched. In some embodiments, the semiconductor layers 204 are completely removed. In the depicted embodiment, the core layers 204a and the intermix layers 205 are completely removed, thus remaining semiconductor layers 206 only include the core layers 206a. In some other embodiments, the core layers 204a are completely removed, while the intermix layers 205 are partially removed, thus the core layers 206a and the remaining portion of the intermix layers 205 collectively form the remaining semiconductor layers 206. For ease of description, regardless of whether the intermix layers 205 are completely removed, the remaining semiconductor layers 206 hereinafter are referred to as core layers 206a.

Various etching parameters can be tuned to achieve selective etching of the core layers 204a and the intermix layers 205, such as etchant composition, etching temperature, etching solution concentration, etching time, etching pressure, source power, Radio-Frequency (RF) bias voltage, RF bias power, etchant flow rate, other suitable etching parameters, or combinations thereof. For example, an etchant is selected for the etching process that etches the material of the core layers 204a (in the depicted embodiment, silicon germanium) at a higher rate than the material of the core layers 206a (in the depicted embodiment, silicon) (i.e., the etchant has a high etch selectivity with respect to the material of the core layers 204a). The intermix layers 205 include certain concentrations of the material of the core layers 204a and thus can be selectively removed with the core layers 204a.

The etching process may include a dry etching process, a wet etching process, other suitable etching process, or combinations thereof. In some embodiments, a dry etching process (such as an RIE process) utilizes a fluorine-containing gas (for example, SF₆) to selectively etch the core layers 204a and the intermix layers 205. In some embodiments, a ratio of the fluorine-containing gas to an oxygen-containing gas (for example, O₂), an etching temperature, and/or an RF power may be tuned to selectively etch silicon germanium or silicon. In some embodiments, a wet etching process utilizes an etching solution that includes ammonium hydroxide (NH₄OH) and water (H₂O) to selectively etch the core layers 204a and the intermix layers 205. In some embodiments, a chemical vapor phase etching process using hydrochloric acid (HCl) selectively etches the core layers 204a and the intermix layers 205.

In the depicted embodiment, the ML includes three suspended core layers 206a vertically stacked that will provide three channels through which current will flow between respective epitaxial source/drain features during operation of the semiconductor structure 200. The core layers 206a are thus referred to as channel layers 206a hereinafter. The channel layers 206a are separated from each other by the openings 214. The channel layers 206a are also separated from the semiconductor substrate 202 by one of the openings 214. A spacing T7 is defined between channel layers 206a along the z-direction. The spacing T7 corresponds to a dimension of the openings 214 along the Z-direction. In the depicted embodiment, the core layers 204a and the intermix layers 205 are completely removed, thus the spacing T7 is equal to (T5+2*T4), which is a sum of thicknesses of one of the core layer 204a and two intermix layers 205. In some other embodiments, the core layers 204a are completely removed while the intermix layers 205 are partially removed, thus the spacing T7 is less than (T5+2*T4). The core layers 204a and the removed intermix layers 205 can be collectively referred to as non-channel layers. In some embodiments, spacings of each openings 214 are substantially the same at different locations on an X-Y plane. For example, the spacing of an opening 214 close to an edge (e.g., a portion directly under the gate spacer 212) is substantially the same (e.g., less than 5% difference) as spacing of the opening 214 at center (e.g., a portion directly under dummy gate stack 210).

In some embodiments, the spacing T7 is within a range between about 2 nm and about 14 nm. In some embodiments, each channel layer 206a has nanometer-sized dimensions and can be referred to as a “nanowire,” which generally refers to a channel layer suspended in a manner that will allow a metal gate to physically contact at least two sides of the channel layer, and in GAA transistors, will allow the metal gate to physically contact at least four sides of the channel layer (i.e., surround the channel layer). In such embodiments, a vertical stack of suspended channel layers can be referred to as a nanostructure, and the process depicted in FIGS. 5A and 5B can be referred to as a channel nanowire release process. In some embodiments, after removing the core layers 204a and the intermix layers 205, an etching process is performed to modify a profile of the channel layers 206a to achieve desired dimensions and/or desired shapes (e.g., cylindrical-shaped (e.g., nanowire), rectangular-shaped (e.g., nanobar), sheet-shaped (e.g., nanosheet), etc.). The present disclosure further contemplates embodiments where the channel layers 206a (nanowires) have sub-nanometer dimensions depending on design requirements of semiconductor structure 200.

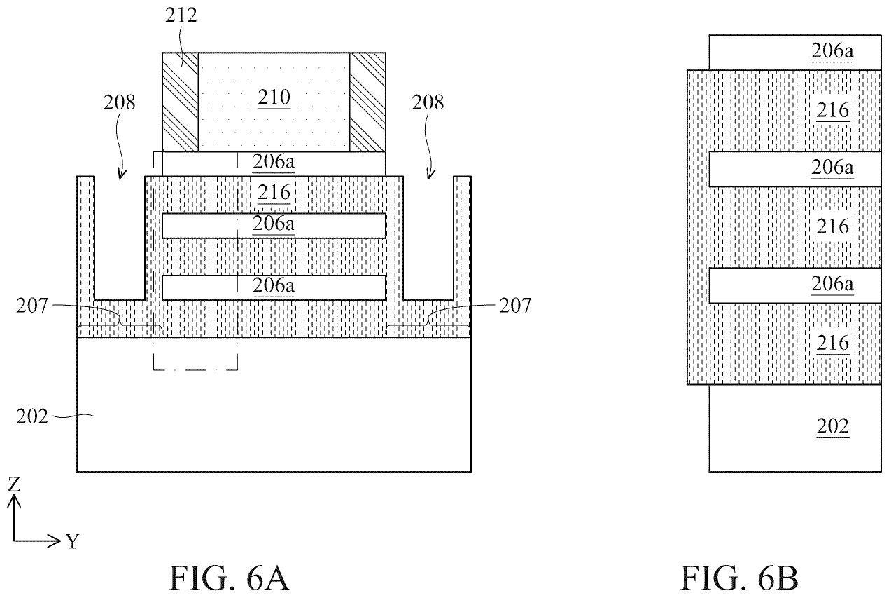

Referring to FIG. 6A, a dielectric material 216 is deposited into the opening 214 and conformally over the source/drain regions 207. FIG. 6B is an enlarged view of a portion (in the dotted rectangle) of the semiconductor structure 200 in FIG. 6A. The depositing the dielectric material can include any suitable methods, such as atomic layer deposition (ALD), plasma enhanced atomic layer deposition (PEALD), physical vapor deposition (PVD), or combinations thereof. In some embodiments, the depositing the dielectric material include an atomic layer deposition (ALD) process. The conformally depositing the dielectric material 216 can form a layer of the dielectric material 216 of a thickness of about 2 nm to about 14 nm. In some embodiments, the thickness is about 2 nm to about 7 nm. In some embodiments, the thickness is about 2 nm to about 5 nm.

The dielectric material 216 can include any suitable materials that have an etching selectively different from the channel layers 206a. In some embodiments, the dielectric material 216 include an oxide material. The dielectric material 216 can include at least one of silicon oxide (SiO₂, SiO), silicon oxynitride (SiON), aluminum oxide (Al₂O₃), silicon nitride, SiOC, SiOCN, and a combination thereof. In some embodiments, the dielectric material 216 includes a composition different from the semiconductor layers 204. In some embodiments, the dielectric material 216 includes less than 0.001% (atomic percentage) of germanium (Ge) or is free of Ge. In some embodiments, the dielectric material 216 is free of SiGe. If the Ge level in the dielectric material 216 is too high (e.g., greater than 1% atomic percentage), the following processes may be impacted by the Ge residue, which will be described in following descriptions.

In some embodiments, unlike the semiconductor layers 204 and 206, the channel layers 206a and the adjacent dielectric material 216 have clear boarders that are free of intermix sessions, which may include a mixture of materials of the channel layers 206a and the dielectric material 216. The channel layers 206a remain substantially unchanged (e.g., less than 5% changes) during the following processes, which will be described in further detail below.

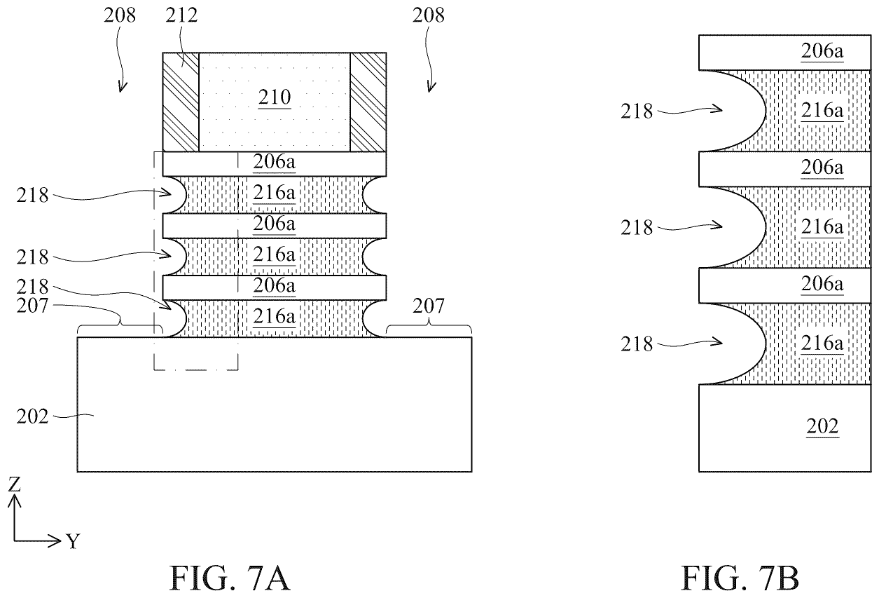

Referring to FIG. 7A, the dielectric material 216 in the source/drain regions 207 is removed, and portions of the dielectric material 216 between the adjacent channel layers 206a (or the semiconductor substrate 202, where applicable) are recessed through exposed sidewall surfaces in the source/drain regions 207 via a selective etching process to form undercuts 218 and dielectric layers 216a (or dielectric interposers 216a). FIG. 7B is an enlarged view of a portion (in the dotted rectangle) of the semiconductor structure 200 in FIG. 7A.

The selective etching process may be any suitable processes, such as a wet etching or a dry etching process. The extent to which the dielectric material 216 are recessed (or the size of the portion removed) is determined by the processing conditions such as the duration the dielectric material 216 is exposed to an etching chemical. In the depicted embodiments, the duration is controlled such that the dielectric material 216 in the source/drain regions 207 is completely removed, and side portions of the dielectric material 216 between adjacent channel layers 206a (or the semiconductor substrate 202, where applicable) are removed, while center portions (e.g., the dielectric layer 216a) of the dielectric material 216 between the adjacent channel layers 206a (or the semiconductor substrate 202, where applicable) remain substantially unchanged. As illustrated in FIG. 7B, the selective etching process creates the undercuts 218, which extend the source/drain recesses 208 into areas beneath the channel layers 206a and the gate spacers 212.

In some embodiments, the undercuts 218 have a convex shape as depicted in FIG. 7B. In some embodiments, the dielectric layers 216a include tip portions extending towards sidewalls of the channel layers 206a (or the semiconductor substrate 202, where applicable). In some embodiments, the tip portions extend to directly contact an entirety of a top or a bottom surface of a channel layer 206a (or the semiconductor substrate 202, where applicable). In such embodiments, the dielectric layers 216a have a sidewall coplanar with a sidewall of the channel layers 206a.

Meanwhile, the channel layers 206a are only slightly affected during the selective etching process. For example, prior to the selective etching process, side portions of the channel layers 206a each has a thickness T3 or T6 (see FIG. 5B). After the selective etching process, thicknesses of the side portions of the channel layers 206a may have about 1% to 5% change from T3 or T6. The etch selectivity between the channel layers 206a and the dielectric material 216 is made possible by the different material compositions between these layers. For example, the dielectric material 216 may be etched away at a substantially faster rate (e.g. more than about 5 times faster or about 10 times faster) than the channel layers 206a. Because spacings of each openings 214 as in FIGS. 5A-5B are substantially the same at different locations on an X-Y plane, and the channel layers 206a (or the semiconductor substrate 202, where applicable) remain substantially unchanged (e.g., less than 5% changes), spacing of each undercuts 218 along the Z-direction is substantially the same as a thickness of each of the dielectric layers 216a (e.g., less than 5% difference), which is about the same as T7.

As discussed above, the selective etching process may be a wet etching process in some embodiments. The etching technique and etchant(s) may be selected to etch the dielectric material 216 without significant etching of the surrounding structures, such as the channel layers 206a. In an embodiment, the channel layers 206a include Si and the dielectric material 216 include an oxide material (e.g., silicon oxide). In an embodiment, a hydrofluoric acid (HF) solution, such as a dilute hydrofluoric acid (DHF), may be used to selectively etch away the dielectric material 216. For example, the dielectric material 216 may be etched away at a substantially faster rate than the channel layers 206a (e.g., with a selectivity greater than 10). As a result, desired portions of the dielectric material 216 (e.g. the side portions of the dielectric material 216 between the adjacent channel layers 206a (or the semiconductor substrate 202, where applicable)) are removed, while the channel layers 206a remain substantially unchanged. The etching duration is adjusted such that the size of the removed portions of the dielectric material 216 are controlled. The optimal condition may be reached by additionally adjusting the etching temperature, dopant concentration, as well as other experimental parameters.

In some embodiments, the selective etching process may include a dry, plasma-free etching process performed using a suitable etch system, such as CERTAS® Gas Chemical Etch System, available from Tokyo Electron Limited, Tokyo, Japan. In some examples, the selective etching process may include etching using a standard clean 1 (SC-1) solution, a solution of ammonium hydroxide (NH₄OH), hydrogen peroxide (H₂O₂) and water (H₂O), hydrofluoric acid (HF), buffered HF, and/or a fluorine (F₂)-based etch. In some examples, the F₂-based etch may include an F₂ remote plasma etch.

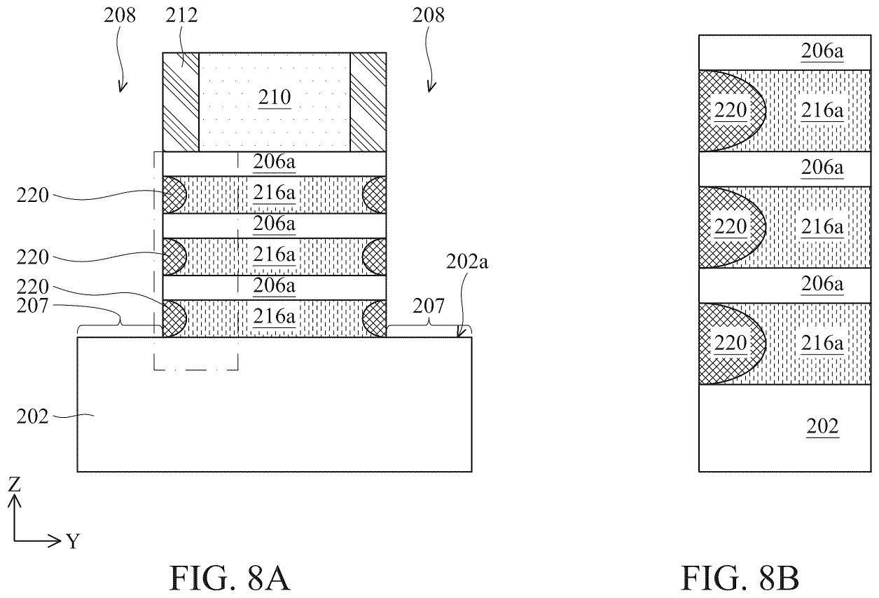

Referring to FIG. 8A, a second dielectric material is deposited into the undercuts 218. Deposition of the second dielectric material forms a spacer layer over the dummy gate stack 210, the gate spacers 212, and over features defining the source/drain recesses 208 (e.g., the channel layers 206a, the dielectric layers 216a, and the semiconductor substrate 202), and includes methods such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the source/drain recesses 208. The deposition process is configured to ensure that the spacer layer fills the undercuts 218. An etching process is then performed that selectively etches the spacer layer to form inner spacers 220 as depicted in FIGS. 8A-8B with minimal (to no) etching of the channel layers 206a, the dummy gate stack 210, and the gate spacers 212. In some embodiments, the spacer layer is removed from sidewalls of the gate spacers 212, sidewalls of the channel layers 206a, the dummy gate stack 210, and the semiconductor substrate 202. The spacer layer (and thus inner spacers 220) includes a material that is different than a material of the channel layers 206a and a material of the gate spacers 212 to achieve a desired etching selectivity during the etching process. In some embodiments, the spacer layer includes a material that is different than a material of the dielectric layers 216a. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material, such as those described herein. In some embodiments, dopants (for example, p-type dopants, n-type dopants, or combinations thereof) are introduced into the dielectric material, such that the spacer layer includes a doped dielectric material.

FIG. 8B is an enlarged view of a portion (in the dotted rectangle) of the semiconductor structure 200 in FIG. 8A. In embodiments, the inner spacers 220 fill the undercuts 218 and thus have a convex shape as depicted in FIG. 8B. In such embodiments, the dielectric layers 216a include tip portions between the inner spacers 220 and the channel layers 206a (or semiconductor substrate 202, where applicable). In some embodiments, the tip portions extend towards a sidewall of the ML but are not exposed to the source/drain recesses 208. In such embodiments, the inner spacers 220 separate the dielectric layers 216a from the source/drain recesses 208. In some other embodiments, although not depicted, the tip portions extend to directly contact an entirety of a top and/or a bottom surface of the channel layers 206a (or the semiconductor substrate 202, where applicable). In such embodiments, the dielectric layers 216a are exposed to the source/drain recesses 208 and separate the adjacent inner spacer 220 from the adjacent channel layers 206a (or the semiconductor substrate 202, where applicable). The dielectric layers 216a can have a sidewall coplanar with a sidewall of the channel layers 206a.

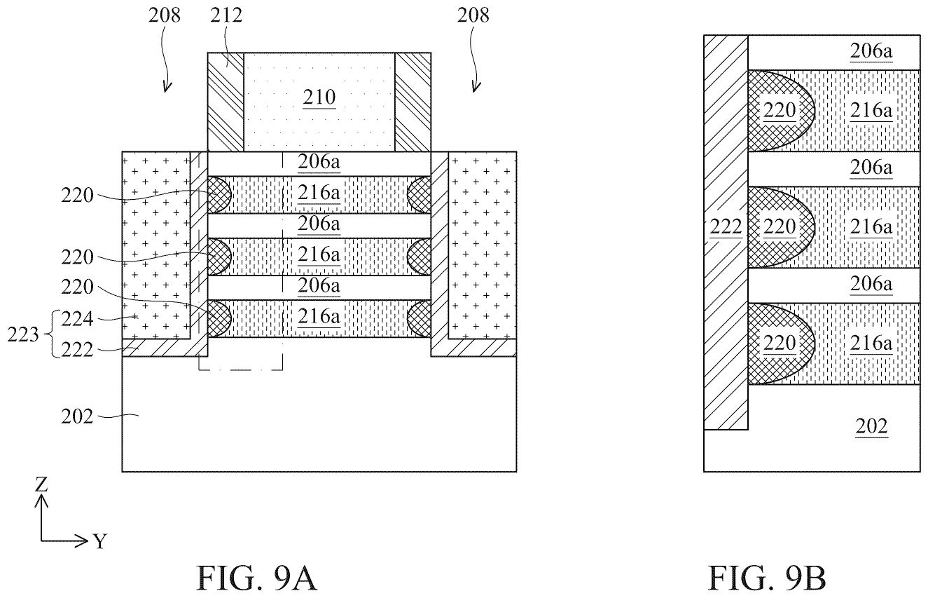

Referring to FIGS. 9A-9B, epitaxial source/drain features 223 are formed in the source/drain recesses 208. FIG. 9B is an enlarged view of a portion (in the dotted rectangle) of the semiconductor structure 200 in FIG. 9A. In some embodiments, one source/drain feature 223 is a source electrode, and the other source/drain feature 223 is a drain electrode. The channel layers 206a that extend from one source/drain feature 223 to the other source/drain feature 223 may form channels of the semiconductor structure 200. Multiple processes including etching and growth processes may be employed to grow the epitaxial source/drain features 223. Each of the epitaxial source/drain features 223 can include multiple layers, such as a first source/drain layer 222 and a second source/drain layer 224. In the depicted embodiment, the epitaxial source/drain features 223 have top surfaces that are substantially aligned with a top surface of the topmost channel layer 206a. However, in other embodiments, the epitaxial source/drain features 223 may alternatively have top surfaces that extend higher than the top surface of the topmost channel layer 206a (e.g. in the Z-direction). In the depicted embodiment, the epitaxial source/drain features 223 occupy a lower portion of the source/drain recesses 208 (e.g. the portion defined by the inner spacers 220 and the channel layers 206a), leaving an upper portion of the source/drain recesses 208 (e.g. the portion defined by the gate spacers 212) open. In some embodiments, the epitaxial source/drain features 223 may merge together, for example, along the X-direction, to provide a larger lateral width than an individual epitaxial feature.

The epitaxial source/drain features 223 may include any suitable semiconductor materials. For example, the epitaxial source/drain features 223 in an n-type GAA device may include Si, SiC, SiP, SiAs, SiPC, or combinations thereof; while the epitaxial source/drain features 223 in a p-type GAA device may include Si, SiGe, Ge, SiGeC, or combinations thereof. The epitaxial source/drain features 223 may be doped in-situ or ex-situ. For example, the epitaxially grown Si source/drain features may be doped with carbon to form silicon: carbon (Si:C) source/drain features, phosphorous to form silicon: phosphor (Si:P) source/drain features, or both carbon and phosphorous to form silicon carbon phosphor (SiCP) source/drain features; and the epitaxially grown SiGe source/drain features may be doped with boron. One or more annealing processes may be performed to activate the dopants in the epitaxial source/drain features 223. The annealing processes may include rapid thermal annealing (RTA) and/or laser annealing processes.

The epitaxial source/drain features 223 may directly interface with sidewalls of the inner spacers 220 and the channel layers 206a. During the epitaxial growth, semiconductor materials grow from the exposed top surface 202a of the semiconductor substrate 202 (e.g., the exposed top surface of doped region) as well as from the exposed side surfaces of the channel layers 206a. It is noted that semiconductor materials do not grow from the surfaces of the inner spacers 220 and the gate spacers 212 during the epitaxial growth process.

Because the semiconductor layers 204 and the intermix layers 205 have been removed, SiGe in the ML when forming the epitaxial source/drain features 223 is negligible (e.g., less than 0.0001% of the total SiGe in the semiconductor layers 204), doping diffusion to undesired regions is reduced, and built-in stress (e.g., tensile stress and compressive stress) during processes is reduced as well.

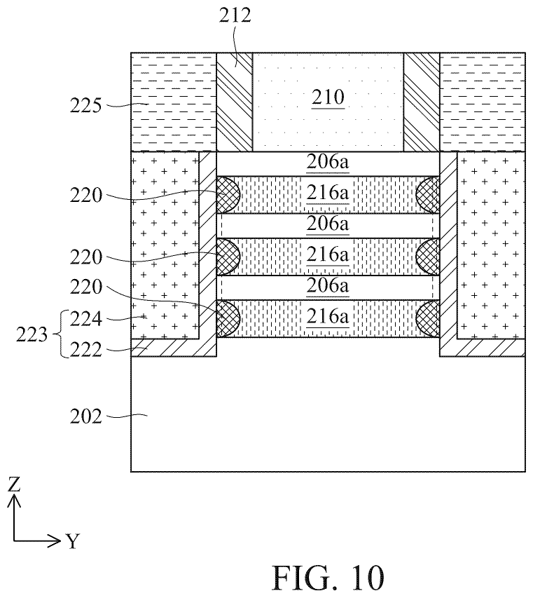

Referring to FIG. 10, an interlayer dielectric (ILD) layer 225 is formed over the epitaxial source/drain features 223 in the remaining spaces of the source/drain recesses 208, as well as vertically over the isolation features 201. The ILD layer 225 may also be formed in between the adjacent dummy gate stacks 210 along the Y-direction, and in between the source/drain features 223 along the X-direction. The ILD layer 225 may include a dielectric material, such as a high-k material, a low-k material, or an extreme low-k material. For example, the ILD layer 225 may include SiO₂, SiOC, SiON, or combinations thereof. The ILD layer 225 may include a single layer or multiple layers, and may be formed by a suitable technique, such as CVD, ALD, and/or spin-on techniques. In some embodiments, a contact etch-stop layer (CESL) is disposed between the ILD layer 225 and the isolation features 201, the epitaxial source/drain features 223 and the gate spacers 212. The CESL includes a material different than the ILD layer 225, such as a dielectric material that is different than the dielectric material of the ILD layer 225 to achieve the etch selectivity. For example, where the ILD layer 225 includes a low-k dielectric material, the CESL includes silicon and nitrogen, such as silicon nitride or silicon oxynitride. Subsequent to the deposition of the ILD layer 225 and/or the CESL, a CMP process and/or other planarization process can be performed to remove excessive portions of the ILD layer 225, thereby planarizing a top surface of the ILD layer 225, until reaching (exposing) a top portion (or top surface) of the dummy gate stack 210. Among other functions, the ILD layer 225 provides electrical isolation between the various components of the semiconductor structure 200.

The ILD layer 225 may be a portion of a multilayer interconnect (MLI) feature disposed over the semiconductor substrate 202. The MLI feature electrically couples various devices (for example, a GAA transistor of the semiconductor structure 200, transistors, resistors, capacitors, and/or inductors) and/or components (for example, gate structures and/or epitaxial source/drain features of GAA transistors), such that the various devices and/or components can operate as specified by design requirements of the semiconductor structure 200. The MLI feature includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of the MLI feature. During operation, the interconnect features are configured to route signals between the devices and/or the components of the semiconductor structure 200 and/or distribute signals (for example, clock signals, voltage signals, and/or ground signals) to the devices and/or the components of the semiconductor structure 200.

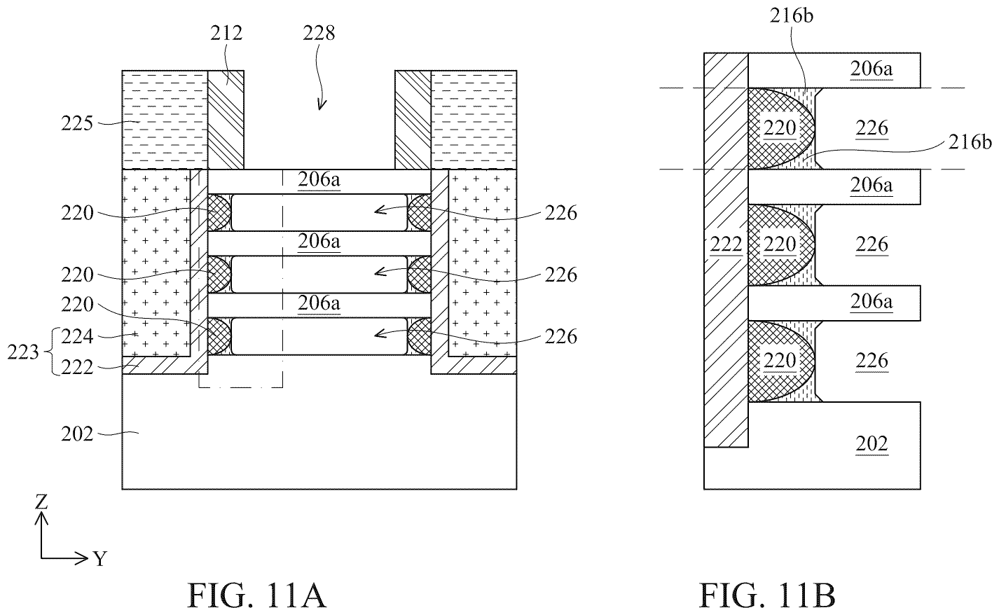

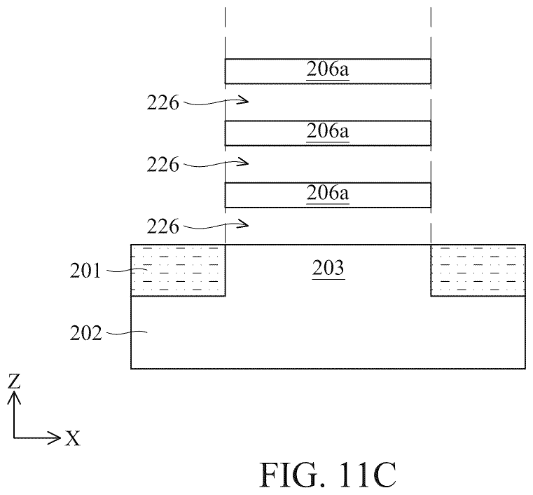

Referring to FIGS. 11A-11C, the dummy gate stack 210 is selectively removed through any suitable lithography and etching processes. In some embodiments, the lithography process includes forming a photoresist layer (resist), exposing the resist to a pattern, performing a post-exposure bake process, and developing the resist to form a masking element, which exposes a region including the dummy gate stack 210. Then, the dummy gate stack 210 is selectively etched through the masking element. In some other embodiments, the gate spacers 212 may be used as the masking element or a part thereof. For example, the dummy gate stack 210 may include polysilicon, the gate spacers 212 and the inner spacers 220 may include dielectric materials, and the channel layers 206a include a semiconductor material. Therefore, an etch selectivity may be achieved by selecting appropriate etching chemicals, such that the dummy gate stack 210 may be removed without substantially affecting the features of the semiconductor structure 200. The removal of the dummy gate stack 210 creates gate trench 228. The gate trench 228 exposes the top surfaces and the side surfaces of the stack of the channel layers 206a and the dielectric layers 216a. In other words, the channel layers 206a and the dielectric layers 216a are exposed at least on two side surfaces in the gate trench 228. Additionally, the gate trench 228 also exposes the top surfaces of the isolation features 201.

Referring to FIGS. 11A-11C, the dielectric layers 216a are also selectively removed through the gate trench 228, for example using wet or dry etching process. The etching chemical is selected such that the dielectric layers 216a have a sufficiently different etching rate as compared to the channel layers 206a, the inner spacers 220, and the gate spacers 212. As a result, the channel layers 206a, the inner spacers 220, and the gate spacers 212 remain substantially unchanged. This selective etching process may include one or more etching steps.

As illustrated in FIGS. 11A-11C, in the present embodiment, the removal of the dielectric layers 216a forms suspended channel layers 206a and openings 226 in between the vertically adjacent layers (e.g. in the Z-direction), thereby exposing the top and bottom surfaces of the channel layers 206a. Each of the channel layers 206a are now exposed circumferentially in the X-Z plane. In addition, the portion of the doped regions of the semiconductor substrate 202 beneath the channel layers 206a are also exposed in the openings 226.

In the examples depicted in FIGS. 11A-11C, the gate trench 228 and the openings 226 vertically adjacent to the gate trench 228 (e.g. in the Z-direction) collectively form an opening having a vertical profile. In other words, the opening collectively formed by the gate trench 228 and its corresponding openings 226 have vertical sidewalls. In some embodiments, such openings having the vertical sidewalls may be formed by a plurality of etch processes. For example, the etch chemistry of the etch process used to remove the dummy gate stack 210 and thereby form the gate trench 228 may include hydrogen bromide (HBr) combined with chlorine (Cl₂), tetrafluoromethane (CF₄), oxygen, or a combination thereof. Furthermore, the etch process used to selectively remove the dielectric layers 216a and thereby form the openings 226 may have an initial etch chemistry including hydrogen bromide (HBr) combined with chlorine (Cl₂), oxygen, or a combination thereof. This initial etch chemistry is followed by a subsequent etch chemistry including hydrogen bromide (HBr) combined with tetrafluoromethane (CF₄), oxygen, or a combination thereof that induces the vertical profile of the opening collectively formed by the gate trench 228 and its corresponding openings 226.

FIG. 11B is an enlarged view of a portion (in the dotted rectangle) of the semiconductor structure 200 in FIG. 11A. In some embodiments, the removal process only removes some, but not all, of the dielectric layers 216a. A portion of the dielectric layers 216a may remain between the inner spacers 220 and the channel layers 206a (or the semiconductor substrate 202, where applicable). Such remaining portion can be referred to as “remaining dielectric layers 216b.”

In some embodiments, the remaining dielectric layers 216b are free of SiGe. In conventional processes, non-channel layers including SiGe are commonly used. After forming epitaxial source/drain features, most of non-channel layers are removed while SiGe residue can remain between adjacent channel layers, causing undesired capacitance between the SiGe residue and adjacent conductive features. In the present disclosure, the semiconductor layers 204 and the intermix layers 205 have been removed, thus SiGe in the ML is negligible (e.g., less than 0.0001% of the total SiGe in the semiconductor layers 204). Therefore, the capacitance between SiGe and other conductive features (e.g., the epitaxial source/drain features 223) is reduced or negligible.

In some embodiments, an etching selectivity of the dielectric layers 216a to the channel layers 206a can be higher than an etching selectivity of the semiconductor layers 204 to the channel layers 206a in conventional processes. In some embodiments, in the removing of the dielectric layers 216a, an etching selectivity of the dielectric layers 216a to the channel layers 206a is greater than 10. If the etching selectivity of the dielectric layers 216a to the channel layers 206a is too small, the channel layers 206a may be etched, thus thicknesses and/or widths of the channel layers 206a may be reduced, which may impact performance of the semiconductor structure 200 (e.g., more SCEs, higher capacitance).

FIG. 11C is a cross-sectional view of the semiconductor structure 200 in FIG. 11A and along the line B-B′ in FIG. 2. In some embodiments, the channel layers 206a has no or little width loss during the removal of the dielectric layers 216a. This can result from the etching selectivity of the dielectric layers 216a to the channel layers 206a, and/or that the channel layers 206a and the adjacent dielectric material 216 have clear boarders that are free of intermix session, as described above. In some embodiments, the channel layers 206a have a width along the X-direction that is equal to or less than a width of a bottom portion of the fin 203 (e.g., a portion of fin 203 contacting the semiconductor substrate 202) along the X-direction by less than 2%. In other words, the width loss of the channel layers 206a in the process is negligible, which improves device performance and reduces capacitance.

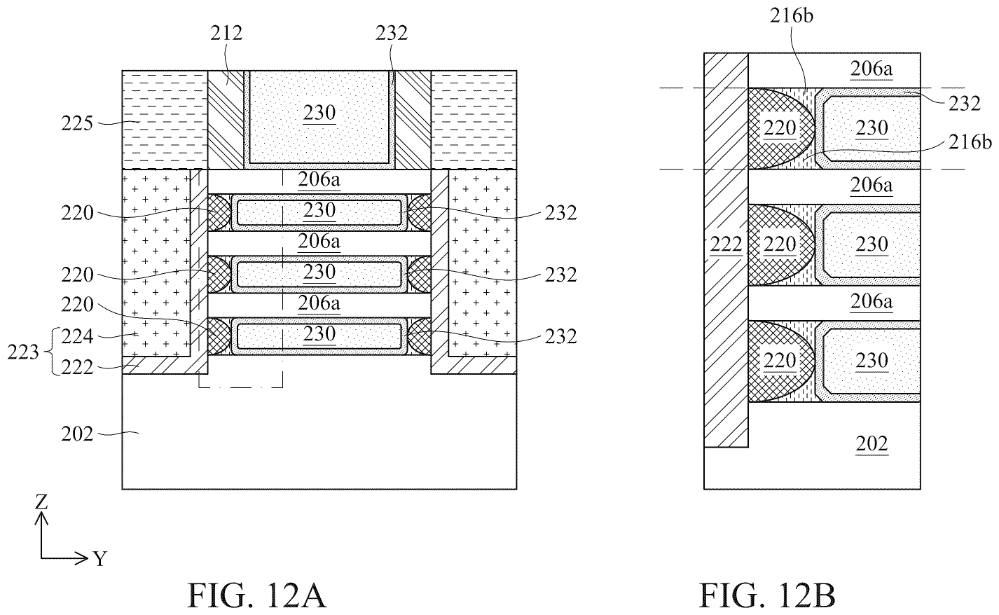

Referring to FIGS. 12A-12B, a metal gate stack is formed. The metal gate stack includes a gate dielectric layer 232 and a gate electrode 230 disposed over the gate dielectric layer 232. For example, the metal gate stack may include a polysilicon gate electrode over a SiON gate dielectric layer. As another example, the metal gate stack may include a metal gate electrode over a high-k dielectric layer. In some instances, a refractory metal layer may interpose between the metal gate electrode (such as an aluminum gate electrode) and the high-k dielectric layer. As yet another example, the metal gate stack may include silicide. The gate dielectric layer 232 is formed between the gate electrode 230 and the channels formed by the channel layers 206a.

In some embodiments, the gate dielectric layer 232 is formed conformally on the semiconductor structure 200. The gate dielectric layer 232 at least partially fills the gate trenches 228. In some embodiments, dielectric interfacial layers may be formed over the channel layers 206a prior to forming the gate dielectric layer 232. Such dielectric interfacial layers improve the adhesion between the channel layers 206a and the gate dielectric layer 232. In the examples depicted in this disclosure, such dielectric interfacial layers are omitted. Instead, in the embodiments shown, the gate dielectric layer 232 is formed around the exposed surfaces of each of the channel layers 206a, such that it wraps around the channel layers 206a in 360 degrees. Additionally, the gate dielectric layer 232 also directly contacts vertical sidewalls of the inner spacers 220, sidewalls of the remaining dielectric layers 216b, and vertical sidewalls of the gate spacers 212. The gate dielectric layer 232 may include a dielectric material having a dielectric constant greater than a dielectric constant of SiO₂, which is approximately 3.9. For example, the gate dielectric layer 232 may include hafnium oxide (HfO₂), which has a dielectric constant in a range from about 18 to about 40. As various other examples, the gate dielectric layer 232 may include ZrO₂, Y₂O₃, La₂O₅, Gd₂O₅, TiO₂, Ta₂O₅, HfErO, HfLaO, HfYO, HfGdO, HfAlO, HfZrO, HfTiO, HfTaO, SrTiO, or combinations thereof. The formation of the gate dielectric layer 232 may be by any suitable processes, such as CVD, PVD, ALD, or combinations thereof.

After forming the gate dielectric layer 232, the gate electrode 230 is formed over the gate dielectric layer 232 to fill the remaining spaces of the gate trenches 228. The gate electrode 230 may include any suitable materials, such as titanium nitride (TiN), tantalum nitride (TaN), titanium aluminide (TiAl), titanium aluminum nitride (TiAlN), tantalum aluminide (TaAl), tantalum aluminum nitride (TaAlN), tantalum aluminum carbide (TaAlC), tantalum carbonitride (TaCN), aluminum (Al), tungsten (W), copper (Cu), cobalt (Co), nickel (Ni), platinum (Pt), or combinations thereof. In some embodiments, a CMP is performed to expose a top surface of the ILD layer 225. The gate dielectric layer 232 and the gate electrode 230 collectively form the metal gate stack, which engages multiple layers within the channel layers 206a (e.g. multiple nanochannels).

FIG. 12B is an enlarged view of a portion (in the dotted rectangle) of the semiconductor structure 200 in FIG. 12A. As previously described in this disclosure, thicknesses along the Z-direction of each channel layers 206a are substantially the same at different locations on an X-Y plane, and the channel layers 206a are substantially unchanged through the process, thus after forming the metal gate stack, thicknesses along the Z-direction of each channel layers 206a remain substantially the same (e.g., less than 5% difference) at different locations on an X-Y plane. If the thicknesses along the Z-direction of each channel layers 206a are not substantially the same (e.g., less than 5% difference) at different locations on an X-Y plane, for example, a thickness on edges (e.g., closer to epitaxial source/drain features) is greater than 10% of a thickness in center (e.g., directly under the metal gate stack above the ML), undesired capacitance may increase. In conventional processes, non-channel layers including SiGe are commonly removed after forming epitaxial source/drain features and before forming the metal gate stack, and the removing of the non-channel layers include multiple etching steps for removal of intermix layers. These multiple etching steps may cause a width reduction of channel layers (e.g., width along x direction) and thicker channel layers on edges (e.g., closer to epitaxial source/drain features) than in center (e.g., directly under the metal gate stack above the ML), thus negatively impacting device performance (e.g., increased SCEs) and increase undesired capacitance. In addition, SiGe in the ML of the present disclosure is negligible (e.g., less than 0.0001% of the total SiGe in the semiconductor layers 204), thus the forming of oxidized Ge during the processes is negligible, which reduces an interface trap effect.

In some embodiments, as depicted in FIG. 12B, in each of the openings 226 between the two adjacent channel layers 206a (or the semiconductor substrate 202, where applicable) (referred to as “top channel layer 206a” and “bottom channel layer 206a”), there are at least one of the remaining dielectric layers 216b (referred as “top remaining dielectric layer 216b” or “bottom remaining dielectric layer 216b”) in direct contact with the top channel layer 206a or the bottom channel layer 206a. The top and/or bottom remaining dielectric layer 216b can have a triangle-like shape in the cross-sectional view as in FIG. 12B. In some embodiments, sidewalls of the top and/or bottom remaining dielectric layer 216b interface with the top and/or bottom channel layer 206a, the adjacent inner spacer 220, and the adjacent gate dielectric layer 232, respectively. In some other embodiments, although not depicted, besides interfacing with these, the top and/or bottom remaining dielectric layer 216b extend to contact with the adjacent epitaxial source/drain feature 223. In such embodiments, the adjacent inner spacer 220 is separated from the top and/or bottom channel layer 206a by the top and/or bottom remaining dielectric layer 216b.

In some embodiments, the top and/or bottom remaining dielectric layer 216b extend between one of the inner spacers 220 (first inner spacer 220) and the gate dielectric layer 232. In some embodiments, the top remaining dielectric layer 216b and the bottom remaining dielectric layer 216b are separated by the first inner spacer 220 and the gate dielectric layer 232 of the metal gate stack. In some other embodiments, the top remaining dielectric layer 216b extends and merges with the bottom remaining dielectric layer 216b. In some embodiments, the top remaining dielectric layer 216b extends to the top channel layer 206a. A top surface of the top remaining dielectric layer 216b and a top surface of the gate dielectric layer 232 can be coplanar, and can be in direct contact with a bottom surface of the top channel layer 206a. Similarly, the bottom remaining dielectric layer 216b extends to the bottom channel layer 206a. A bottom surface of the bottom remaining dielectric layer 216b and a bottom surface of the gate dielectric layers 232 can be coplanar, and can be in direct contact with a top surface of the bottom channel layer 206a.

After forming the gate dielectric layer 232 and the gate electrode 230, a planarization process is performed to remove excess gate materials from the semiconductor structure 200. For example, a CMP process is performed until a top surface of the ILD layer 225 is reached (exposed), such that a top surface of the metal gate stack is substantially planar with the top surface of the ILD layer 225 after the CMP process. Accordingly, the semiconductor structure 200 can include a GAA transistor having a metal gate stack wrapping respective channel layers 206a, such that the metal gate stack is disposed between respective epitaxial source/drain features 223.

Fabrication can proceed to continue fabrication of the semiconductor structure 200. For example, various contacts can be formed to facilitate operation of the GAA transistor. For example, one or more ILD layers, similar to the ILD layer 225, and/or CESL layers can be formed over the semiconductor substrate 202 (in particular, over the ILD layer 225 and the metal gate stack). Contacts can then be formed in the ILD layer 225 and/or ILD layers disposed over the ILD layer 225. For example, a contact is electrically and/or physically coupled with the metal gate stack and another contact is electrically and/or physically coupled to source/drain regions of the GAA transistor (particularly, the epitaxial source/drain features 223). Contacts include a conductive material, such as metal. Metals include aluminum, aluminum alloy (such as aluminum/silicon/copper alloy), copper, copper alloy, titanium, titanium nitride, tantalum, tantalum nitride, tungsten, polysilicon, metal silicide, other suitable metals, or combinations thereof. The metal silicide may include nickel silicide, cobalt silicide, tungsten silicide, tantalum silicide, titanium silicide, platinum silicide, erbium silicide, palladium silicide, or combinations thereof. In some implementations, the ILD layers disposed over the ILD layer 225 and the contacts (for example, extending through the ILD layer 225 and/or the other ILD layers) are a portion of the MLI feature described above.

Other fabrication processes may be applied to the semiconductor structure 200 and may implemented before, during, or after the processes described above, such as various processing steps to form an interconnect structure over the GAA transistors from the frontside of the semiconductor substrate 202 to electrically connects various circuit components. The interconnect structure includes metal lines distributed in multiple metal layers (such as 1^{st} metal layer, 2^{nd} metal layer, 3^{rd} metal layer, and etc. from the bottom up to the top metal layer) to provide horizontal routing and contact features (between the substrate and the first metal layer, and via features (between the metal layers) to provide vertical routing. The semiconductor structure 200 also includes other components, such as other conductive features (such as redistribution layer or RDL), passivation layer(s) to provide sealing effect, and/or bonding structures to provide an interface between the semiconductor structure 200 and a circuit board (such as a printed circuit board) to be formed on the interconnect structure.

Though not intended to be limiting, embodiments of the present disclosure offer benefits for semiconductor processing and semiconductor devices. For example, by removing the non-channel layers including the transition layers before forming the epitaxial source/drain features, SiGe residue becomes negligible before forming the epitaxial source/drain features, thus abnormal doping diffusion and built-in stress (e.g., tensile stress and compressive stress) during following processes are reduced. The early removal of the transition layers also reduces undesired capacitance and device degradation, avoids width loss of channel layers, thus improves performance of the device, reduces short-channel effects (SCEs), and can result in higher current drive and higher logic density.

The fabrication process flow for fabricating the semiconductor structure 200 discussed above may be referred to as a dummy oxide interposer (DOI) process flow, in which the dielectric material 216 (etched to form the dielectric layers 216a of FIG. 7A) serves as a dummy oxide interposer. As discussed above with reference to FIG. 12A, such a dummy oxide interposer is eventually removed and replaced by the metal gate stack that includes the gate dielectric layer 232 and the gate electrode 230. However, before the formation of the gate electrode 230, additional fabrication processes may be performed to tune a threshold voltage of the semiconductor structure 200. For example, referring now to FIGS. 13A-13B, diagrammatic fragmentary cross-sectional side views of a portion of a semiconductor structure 300 similar to the semiconductor structure 200 is illustrated. The portion of the semiconductor structure 300 illustrated in FIG. 13A includes a plurality of channel layers 206a, which may contain a semiconductor material such as silicon in some embodiments. A gate dielectric layer 232 is formed to circumferentially surround each of the channel layers 206a in the cross-sectional side view. A dipole layer 310 is formed to circumferentially surround each of the gate dielectric layers 232 in the cross-sectional side view. As discussed above, the dipole layer 310 may include dopants, which may be driven into the gate dielectric layer 232 (see FIG. 13B) by one or more annealing processes. The dipole layer 310 is eventually removed, and a gate electrode (e.g., the gate electrode 230) may be formed over the gate dielectric layer 232 that is now doped.

However, the geometric profile of the channel layers 206a of the semiconductor structure 300 may give rise to certain challenges. For example, as an inherent result of the fabrication process flow discussed above with reference to FIGS. 2-12, each of the channel layers 206a may have a somewhat square shape in the cross-sectional side view. Due to such a square-like shape of the channel layers 206a, the resulting dipole layer 310 may have thicker corner regions 320 compared to the rest of the dipole layer 310. The thicker corner regions 320 of the dipole layer 310 will in turn lead to a greater amount of dipole dopants 330 in the corner regions 320 of the doped gate dielectric layer 232. In other words, the dipole dopants 330 may be congregated disproportionately more in the corner regions 320 of the doped gate dielectric layer 232 than in other parts of the doped gate dielectric layer 232. This is because the thicker corner regions 320 of the dipole layer 310 will cause the corner regions 320 of the gate dielectric layer 232 (which is directly below the dipole layer 310) to absorb more dipole dopants 330. Such an uneven distribution of the dipole dopants 330 may be referred to as dipole loading effect, which may lead to suboptimal device performance.

The present disclosure addresses the dipole loading issue discussed above by forming a sufficiently thick dipole layer, so as to cause the dipole layers formed over different gate dielectric layers to merge into one another. Thereafter, annealing processes with specifically configured parameters are performed to cause the dipole dopants to distribute more uniformly around the gate dielectric layers. For example, whereas the dipole layer 310 in some other implementations is formed to be relatively thin (such that a gap remains between the dipole layers 310 wrapping around individual gate dielectric layers 232), the dipole layer 310 in FIG. 13A is formed to have a sufficient thickness 360, such that the gaps 370 between vertically adjacent ones of the gate dielectric layers 232 are filled by the dipole layer 310. In other words, the different portions of the dipole layer 310 wrapping around individual ones of the gate dielectric layers 232 (and their respective channel layers 206a) are merged together vertically, so that the dipole layer 310 for each stack may be considered as a single layer, as opposed to multiple distinct layers surrounding their respective gate dielectric layers 232 and channel layers 206a. To ensure the merging of the dipole layer 310 (or the filling of the gap 370), the thickness 360 of the dipole layer 310 is configured to exceed ½ of a vertical dimension 375 of the gap 370. In some embodiments, the thickness 360 is configured to be in a range between about 10 angstroms and about 40 angstroms.

The unique way in which the dipole layer 310 is formed helps to promote the uniformity of the dipole dopant distribution in the gate dielectric layer 232. For example, as shown in FIG. 13B, one or more annealing processes 380 may be performed to the semiconductor structure 400 to drive the dipole dopants 330 into the gate dielectric layer 232. Since the dipole layer 310 was sufficiently thick all around, the corner regions thereof are no longer dominating the dipole dopant distribution, even though the channel layer 206 has a square-like shape. Instead, the dipole dopants 330 spread more evenly all around the gate dielectric layer 232 underneath.

It is understood that the annealing processes 380 may also be carefully configured to facilitate the more uniform spreading of the dipole dopants 330 in the gate dielectric layer 232. For example, the annealing processes 380 may include a first annealing process performed at a temperature range between about 500 degrees C. and about 800 degrees C., as well as a second annealing process performed at a temperature range between about 800 degrees C. and about 1200 degrees C. The first annealing process may cause a formation of an intermixing layer that comprises a portion of the gate dielectric layer 232 with the dipole dopants 330 mixed therein. The intermixing layer may reach about 10% and about 50% of a depth of the gate dielectric layer 232. The second annealing process may also be referred to as a drive-in process, which causes the dipole dopants 330 to reach substantially an entire depth of the dipole layer 310. Alternatively stated, the second annealing process may effectively extend the intermixing layer substantially all the way through the dipole layer 310.

In any case, after the completion of the annealing processes 380, the dipole layer 310 is removed, and the gate dielectric layer 232 becomes a doped gate dielectric layer 232, where the dipole dopants 330 are distributed relatively uniformly throughout the doped gate dielectric layer 232. A gate electrode (e.g., the gate electrode 230) may then be formed over the doped gate dielectric layer 232. The resulting GAA transistor may have improved performance compared to other GAA transistors that have square-like channel profiles.

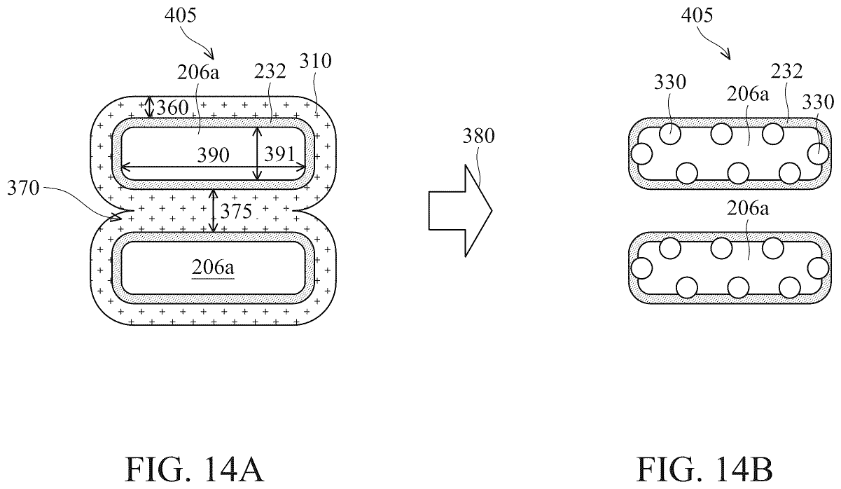

Note that the dipole loading effect may impact not only devices with square-like channel layers 206 (e.g., a GAA formed as a result of the fabrication process flow described in FIGS. 2-12), but also devices with relatively small active region widths too. For example, referring now to FIGS. 14A-14B, a semiconductor structure 405 (also a part of a GAA device) may also have a plurality of channel layers 206, a plurality of gate dielectric layers 232 formed to circumferentially surround the channel layers 206, and a plurality of dipole layers 310 formed to circumferentially surround the gate dielectric layers 232. Here, the cross-sectional profile of the channel layers 206a of the semiconductor structure 405 of FIG. 14A may or may not be as square as the cross-sectional profile of the channel layers 206a of the semiconductor structure 300 of FIG. 13A. However, the channel layers 206a of the semiconductor structure 405 may be substantially narrower than the channel layers 206a of the semiconductor structure 300. The small width of the channel layer 206a is represented by a lateral dimension 390, which is not too long compared to a vertical dimension 391 (i.e., a thickness) of the channel layer 206a. In some embodiments, a ratio of the lateral dimension 390 and the vertical dimension 391 is in a range between about 4:1 and about 40:1. In some embodiments, the lateral dimension 390 is in a range between about 150 angstroms and about 1500 angstroms.

Due to the relatively small width of the channel layers 206a, the dipole layer 310 formed on the channel layers 206a may also have thicker corner regions. As such, once annealing processes are performed to drive the dipole dopants 330 into the gate dielectric layer 232, the dipole dopant distribution could be susceptible to the dipole dopant loading effect (e.g., the dipole dopant being more concentrated near the corner regions of the gate dielectric layer 232 than the rest of the gate dielectric layer 232), which also leads to suboptimal device performance.

To reduce the dipole loading effect, a sufficiently thick dipole layer 310 may also be formed around the channel layers 206a of a semiconductor structure 405. Similar to the embodiment of FIGS. 13A-13B, the thickness 360 of the dipole layer 310 is still configured to be sufficiently high (e.g., exceeding ½ of the vertical dimension of the gap 370 separating vertically adjacent gate dielectric layers 232 in the semiconductor structure 405), such that the dipole layer 310 will merge together vertically so as to fill the gap 370. Thereafter, the one or more annealing processes 380 (e.g., a two-step annealing process described above with reference to FIGS. 13A-13B) may be performed to drive the dipole dopants 330 uniformly into the gate dielectric layer 232. The dipole layer 310 is then removed, and a gate electrode may then be formed over the doped gate dielectric layer 232. The resulting GAA transistor may also have enhanced performance compared to other GAA transistors with a relatively small channel width.

FIGS. 15-28 illustrate a series of diagrammatic fragmentary cross-sectional side views of the semiconductor structure 400 at various stages of fabrication according to an embodiment of the present disclosure. FIGS. 15-28 correspond to cross-sections taken at a Y-Z plane, and therefore they may be referred to as Y-cut views.

Referring now to FIG. 15, the semiconductor structure 400 includes at least two different vertical stacks 410A and 410B. Each of the vertical stacks 410A and 410B includes a channel layer 206a, an interfacial layer 231 (e.g., silicon oxide) formed on the channel layer 206a, a gate dielectric layer 232 formed on the interfacial layer 231, and a hard mask layer 420 formed on the gate dielectric layer 232. It is understood that in actual fabrication, the interfacial layer 231 may circumferentially surround the channel layer 206a, the gate dielectric layer 232 may circumferentially surround the interfacial layer 231, and the hard mask layer 420 may circumferentially surround the gate dielectric layer 232. However, the circumferential surrounding aspect is not specifically shown in FIGS. 15-28 for reasons of simplicity. It is also understood that each of the vertical stacks 410A and 410B may include multiple ones of the channel layer 206a, the interfacial layer 231, the gate dielectric layer 232, and the hard mask layer 420, but for the reasons of clarity and simplicity, FIGS. 15-28 illustrate one instance of the channel layer 206a, the interfacial layer 231, the gate dielectric layer 232, and the hard mask layer 420.

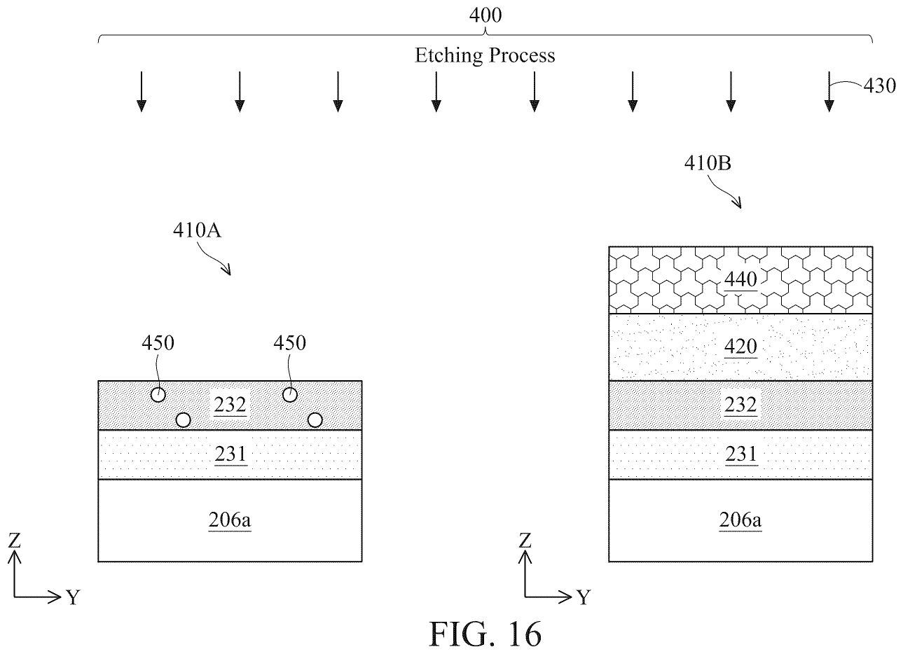

Referring now to FIG. 16, an etching process 430 is performed to the semiconductor structure 400. As a part of the etching process 430, a patterning layer 440 (e.g., a photoresist layer) is formed to cover the stack 410B while leaving the stack 410A exposed. Thereafter, the etching process 430 removes the hard mask layer 420 in the stack 410A, while the patterning layer 440 serves as a protective layer to prevent the hard mask layer 420 in the stack 410B from being etched. As a result of the etching process 430, the surfaces of the gate dielectric layer 232 in the stack 410A is exposed.

As shown in FIG. 16, etchant particles 450 (e.g., as remnants of the etchant of the etching process 430) may be found in the gate dielectric layer 232 of the stack 410A, but not in the gate dielectric layer 232 of the stack 410B. This is because the exposed surfaces of the gate dielectric layer 232 may allow some of the etchant particles 450 to penetrate into the gate dielectric layer 232 of the stack 410A, while the patterning layer 440 and/or the hard mask layer 420 prevents the etchant particles 450 from reaching the gate dielectric layer 232 of the stack 410B. In some embodiments, a concentration of the etchant particles 450 in the gate dielectric layer 232 in the stack 410A may be in a range between about 0.2% and about 4%.

In some embodiments, the etchant particles 450 may even be found in the interfacial layer 231 of the stack 410A. However, since the interfacial layer 231 is located beneath the gate dielectric layer 232, the concentration (or amount) of the etchant particles 450 in the interfacial layer 231 may be lower than the concentration (or amount) of the etchant particles 450 in the gate dielectric layer 232. In some embodiments, the etching process 430 is performed using an etchant that contains nitrogen (N) or oxygen (O). For example, the etchant may include N-based radicals or O-based radicals. As such, the etchant particles 450 that can be found in the gate dielectric layer 232 or the interfacial layer 231 of the stack 410A may include nitrogen or oxygen. In any case, it is understood that the presence of the etchant particles 450 in the gate dielectric layer 232 (and possibly in the interfacial layer 231) of the stack 410A (but not in the stack 410B) is one of the inherent and unique results of the unique fabrication process flow being performed herein.

It is also understood that the etching process 430 may lead to a slight reduction in height of the gate dielectric layer 232 of the stack 410A. In other words, although the etching process 430 may be configured to stop etching once the gate dielectric layer 232 is reached, this may not be perfect in real world situations. In some cases, a small amount of the gate dielectric layer 232 in the stack 410A may still be etched away before the etching process 430 is fully stopped. As a result, the thickness (in the Z-direction) of the gate dielectric layer 232 in the stack 410A may be slightly less than the thickness of the gate dielectric layer 232 in the stack 410B at this stage of fabrication.

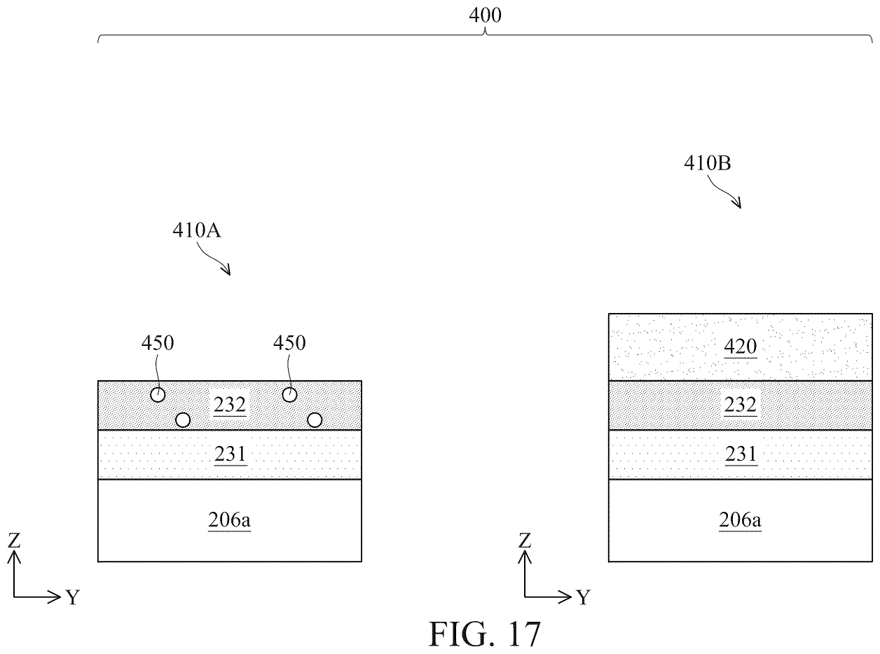

Referring now to FIG. 17, the patterning layer 440 is removed. For example, the patterning layer 440 may be removed via a photoresist stripping process or a photoresist ashing process. The removal of the patterning layer 440 exposes the surfaces of the hard mask layer 420 that is in the stack 410B.

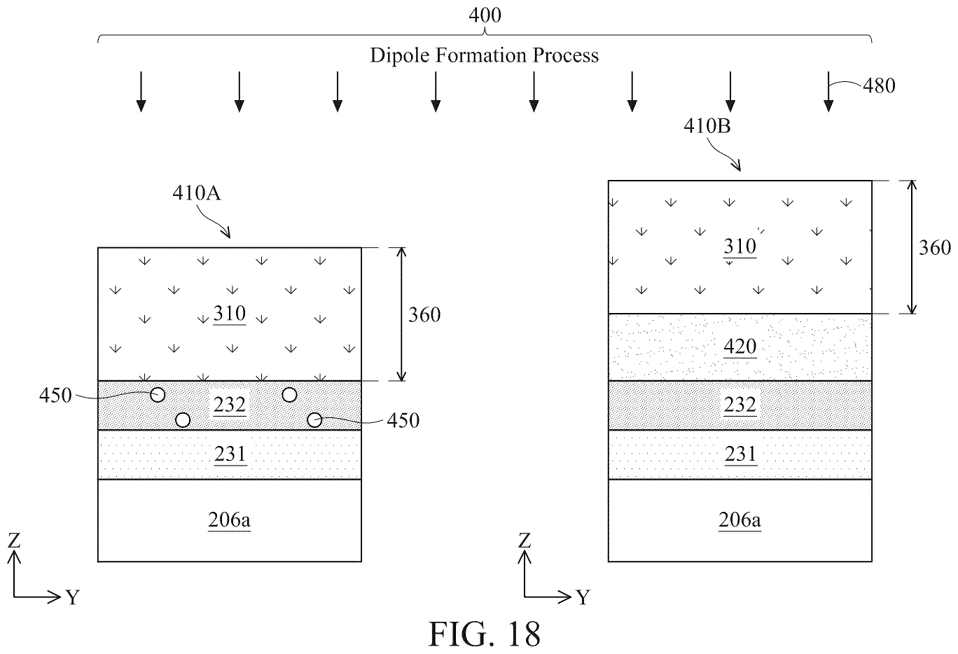

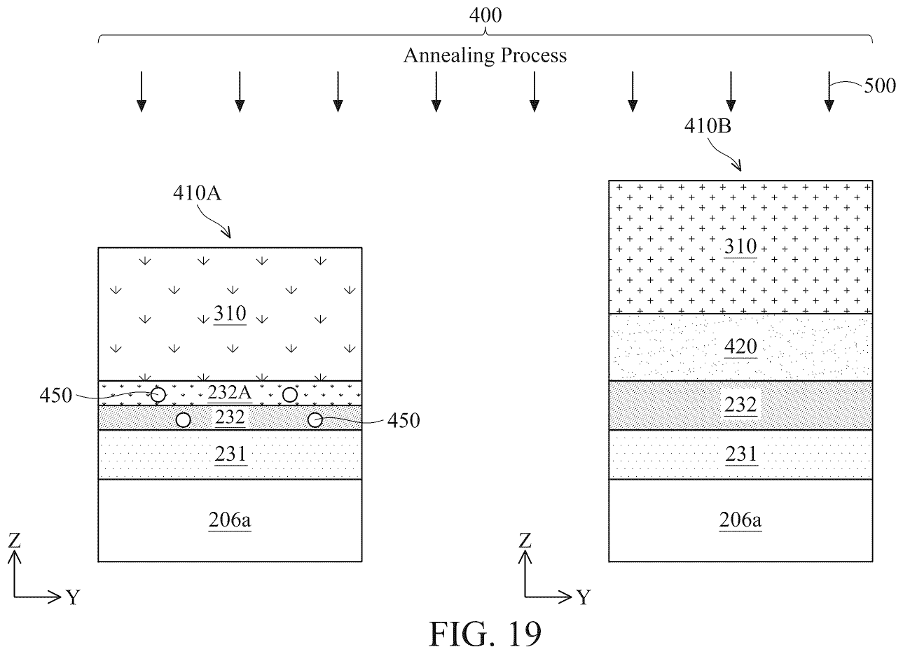

Referring now to FIG. 18, a dipole formation process 480 is performed to the semiconductor structure 400. In some embodiments, the dipole formation process 480 may utilize one or more deposition processes, such as chemical vapor deposition (CVD), physical vapor deposition (PVD), atomic layer deposition (ALD), or combinations thereof, to deposit a tunable p-dipole dopant material or a tunable n-dipole dopant material over the gate dielectric layer 232 of the stack 410A or over the hard mask layer 420 of the stack 410B. In some embodiments, the tunable p-dipole dopant material may include AlO_{d}, ZnOₑ, GaO_{f}, or combinations thereof (where x, y, and z are positive integers). In some embodiments, the tunable n-dipole dopant material may include LaOₐ, YO_{b}, ScO_{c}, or combinations thereof (where x, y, and z are positive integers).

As a result of the dipole formation process 480, a segment of the dipole layer 310 is formed on the gate dielectric layer 232 in the stack 410A, and another segment of the dipole layer 310 is formed on the hard mask layer 420 in the stack 410B. As discussed above, the dipole layer 310 is formed to circumferentially surround (see FIG. 13A) the gate dielectric layer 232 (in the case of the stack 410A) or the hard mask layer 420 (in the case of the stack 410B), even though this circumferential surrounding aspect is not specifically illustrated in FIG. 18 for reasons of simplicity.

As discussed above with reference to FIGS. 13A-13B and 14A-14B, the thickness 360 of the dipole layer 310 is configured (e.g., by adjusting the length of the deposition time of the dipole formation process 480) to be sufficiently thick to ensure that the dipole layer 310 will fill the gap 370 between the vertically adjacent ones of the gate dielectric layers 232 (see FIG. 13A). In some embodiments, the thickness 360 is in a range between about 10 angstroms and about 40 angstroms.

Referring now to FIG. 19, an annealing process 500 is performed to the semiconductor structure 400. The annealing process 500 may be the first step of the annealing process 380 discussed above with reference to FIGS. 13A-13B. In some embodiments, the annealing process 500 is performed at a process temperature in a range between about 500 degrees C. and about 800 degrees C. In some embodiments, the annealing process 500 is performed for a duration in a range between about 1 second and about 5 minutes. In some embodiments, the annealing process 500 includes a spike annealing process. The annealing process 500 help to facilitate a movement of the dopant atoms from the dipole layer 310 into the gate dielectric layer 232. In other words, the annealing process 500 causes a portion of the gate dielectric layer 232A of the stack 410A to intermix with the dipole layer 310 formed thereon. As such, the annealing process 500 may also be referred to as an intermixing process. The result is that the intermixed portion of the gate dielectric layer 232A may become doped with the dopant of the dipole layer 310. In some embodiments, the thickness of the intermixed portion of the gate dielectric layer 232A is in a range between about 10% and about 50% of the depth (or thickness) of the gate dielectric layer 232.

While the annealing process 500 causes the dopants of the dipole layer 310 to penetrate partially into the gate dielectric layer 232 of the stack 410A, the presence of the hard mask layer 420 prevents the dopants of the dipole layer 310 of the stack 410B from penetrating into the gate dielectric layer 232 of the stack 410B. In other words, the selective formation of the hard mask layer 420 in the stack 410B but not in the stack 410A allows the gate dielectric layer 232 of the stack 410A to become partially doped with the dipole dopants but prevents the gate dielectric layer 232 of the stack 410B from being doped. At this stage of fabrication, the stack 410A includes a partially doped gate dielectric layer 232 (e.g., the intermixed portion of the gate dielectric layer 232A), while the gate dielectric layer 232 in the stack 410B remains undoped.

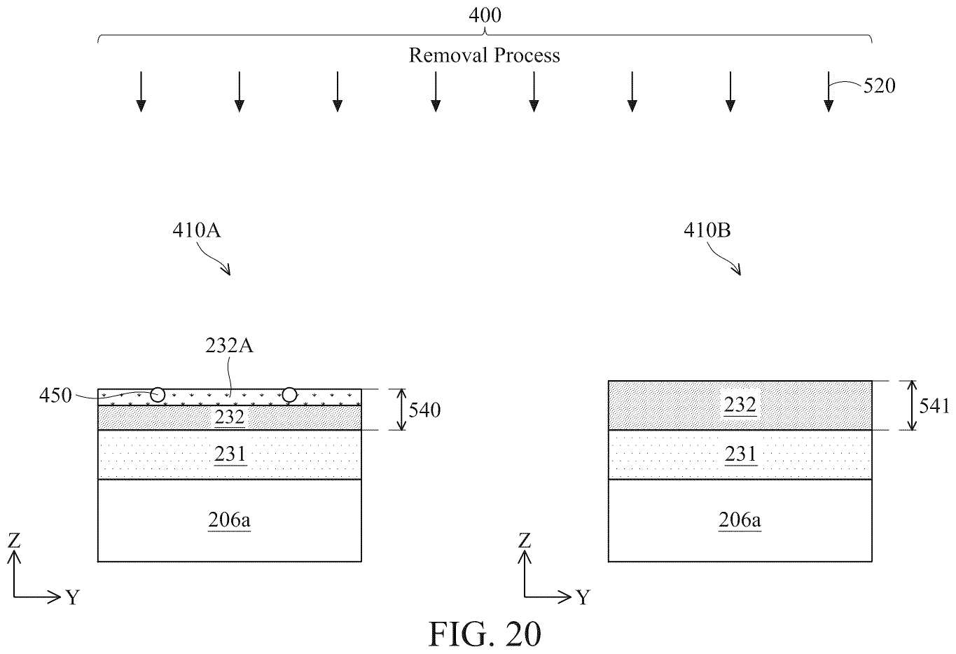

Referring now to FIG. 20, after the annealing process 500 has been performed (resulting in the formation of the intermixed portion of the gate dielectric layer 232A in the stack 410A), the dipole layer 310 of the stack 410A, as well as the dipole layer 310 and the hard mask layer 420 of the stack 410B, are removed using one or more removal processes 520. In some embodiments, the removal processes 520 may include one or more etching processes configured to etch away the dipole layer 310 in the stack 410B, and/or one or more etching processes configured to etch away the hard mask 420 in the stack 410B.

Although these etching processes may be configured with an etching selectivity between the intermixed portion of the gate dielectric layer 232A and the dipole layer 31, as well as between the intermixed portion of the gate dielectric layer 232A and the hard mask later 420, some portions of the intermixed portion of the gate dielectric layer 232A may still be etched away. For example, the gate dielectric layer 232 and the hard mask layer 420 may have different dielectric material compositions, but it may be difficult to tune the etching selectivity to be sufficiently high so that only the hard mask layer 420 is etched without affecting the gate dielectric layer 232. Consequently, an inherent result of the unique fabrication process flow performed herein is that the gate dielectric layer 232 (including the intermixed portion 232A) of the stack 410A may be thinner than the gate dielectric layer 232 of the stack 410B. For example, the gate dielectric layer 232 (including the intermixed portion 232A) of the stack 410A may have a thickness 540 in the Z-direction, and the gate dielectric layer 232 of the stack 410B may have a thickness 541 in the Z-direction, where the thickness 541 is greater than the thickness 540.

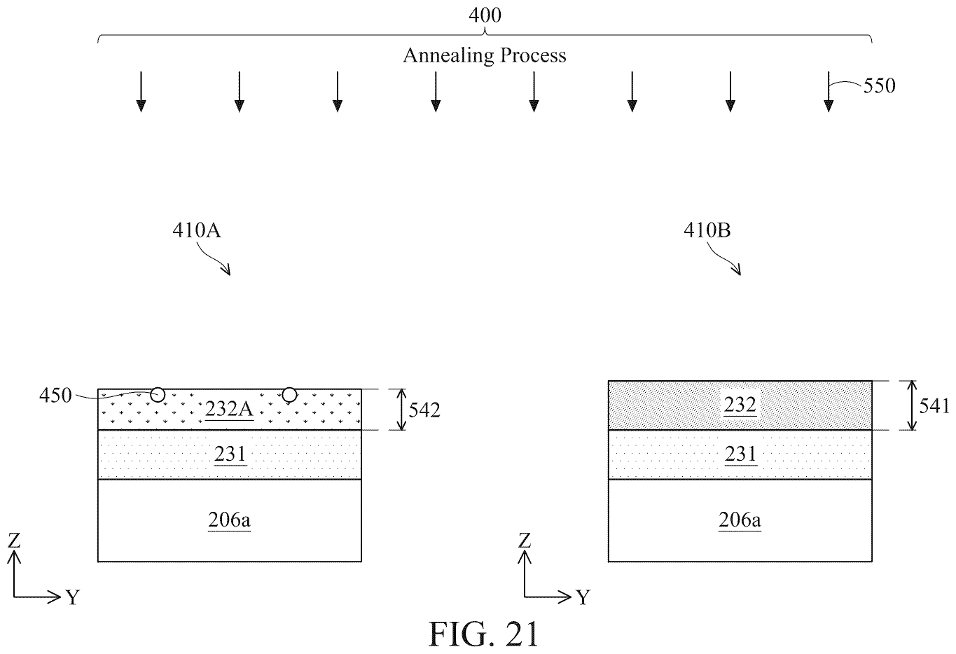

Referring now to FIG. 21, another annealing process 550 is performed to the semiconductor structure 400. The annealing process 550 may be the second step of the annealing process 380 discussed above with reference to FIGS. 13A-13B. The annealing process 550 is performed at a greater temperature than the annealing process 500. In some embodiments, the annealing process 550 is performed at a process temperature in a range between about 800 degrees C. and about 1200 degrees C. In some embodiments, the annealing process 550 is performed for a duration in a range between about 1 second and about 5 minutes. In some embodiments, the annealing process 550 includes a spike annealing process. The annealing process 550 further drives the dopant atoms of the intermixed portions of the gate dielectric layer 232A into the rest of the gate dielectric layer 232 of the stack 410A. As such, the annealing process 550 may also be referred to as a dipole drive-in process. As a result of the annealing process 550, a substantial entirety of the gate dielectric layer 232A is now doped.

At this stage of fabrication, the doped gate dielectric layer 232A may have a thickness 542, which may be less than or equal to the thickness 540 of FIG. 20. For example, in some embodiments, the drive-in of the dipole dopants to the rest of the gate dielectric layer 242 may lead to a small thickness loss of the gate dielectric layer 232, in which case the thickness 542 may be slightly less than the thickness 540. In other embodiments, the thickness loss of the gate dielectric layer 232 as a result of the dopant drive-in may be negligible, in which case the thickness 542 may still be substantially equal to the thickness 540. In any case, the thickness 542 of the doped gate dielectric layer 232A is still less than the thickness 541 of the un-doped gate dielectric layer 232 of the stack 410B.

In some embodiments, the thickness 542 is in a range between about 10 angstroms and about 20 angstroms, and a difference between the thickness 541 and the thickness 542 is in a range between about 0.2 angstroms and about 2 angstroms. In some embodiments, a ratio of the difference between the thicknesses 541 and 542 and the thickness 542 is in a range between about 1:100 and about 1:5. It is understood that the difference between the thicknesses 542 and 541 may also be attributed at least in part to the etching process 430 discussed above with reference to FIG. 16. In any case, the difference between the thicknesses 542 and 541 is one of the unique physical characteristics of the semiconductor structure 400 and may be used to evaluate whether a semiconductor structure was fabricated using the unique fabrication process flow of the present disclosure.

Another unique physical characteristic of the semiconductor structure 400-which is another inherent result of the unique fabrication process flow of the present disclosure being performed—is that remnants of the etchant particles 450 may be found in the doped gate dielectric layer 232A (and even in the interfacial layer 231 in some embodiments) of the stack 410A, but not in the un-doped gate dielectric layer 232 of the stack 410B. As discussed above, the presence of the etchant particles 450 in the stack 410A but not in the stack 410B may be attributed to the fact that the patterning layer and/or the hard mask layer 420 may prevent the etchant particles 450 from reaching the gate dielectric layer 232 of the stack 410B during the etching process 430, while the exposed surfaces of the gate dielectric layer 232 of the stack 410A may allow the etchant particles 450 to penetrate into the gate dielectric layer 232 (and possibly the interfacial layer 231) of the stack 410A. This unique physical characteristic may also be used to evaluate whether a semiconductor structure was fabricated using the unique fabrication process flow of the present disclosure.

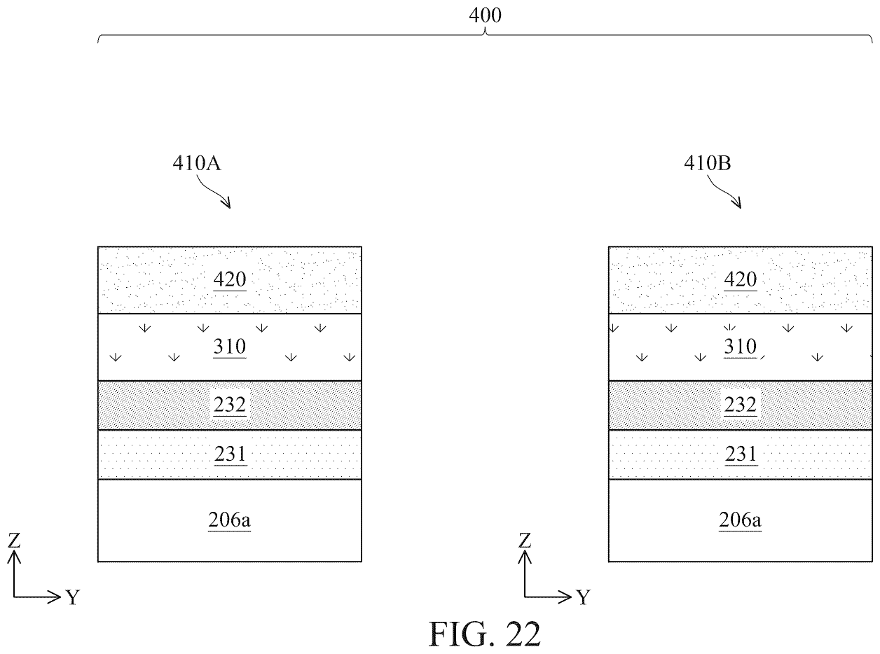

FIGS. 15-21 correspond to one embodiment of a process flow of the present disclosure. FIGS. 22-27 correspond to another embodiment of a process flow of the present disclosure. FIGS. 22-27 also illustrate a series of diagrammatic fragmentary cross-sectional side views (taken at a Y-Z plane) of the semiconductor structure 400 at various stages of fabrication. For reasons of consistency and clarity, similar components appearing in FIGS. 22-27 will be labeled in the same as they were in FIGS. 15-21.

Referring now to FIG. 22, the semiconductor structure 400 includes the vertical stacks 410A and 410B, which each includes the channel layer 206a, the interfacial layer 231, the gate dielectric layer 232, and the hard mask layer 420. However, unlike the embodiment of FIG. 15, the vertical stacks 410A and 410B of FIG. 22 also each include a dipole layer 310 that is disposed between the gate dielectric layer 232 and the hard mask layer 420. In other words, whereas the embodiment of FIGS. 15-21 forms the dipole layer 310 at a later fabrication stage, the embodiment of FIG. 22 forms the dipole layer 310 on the gate dielectric layer 232, and then the hard mask layer 420 is formed on the dipole layer 310.

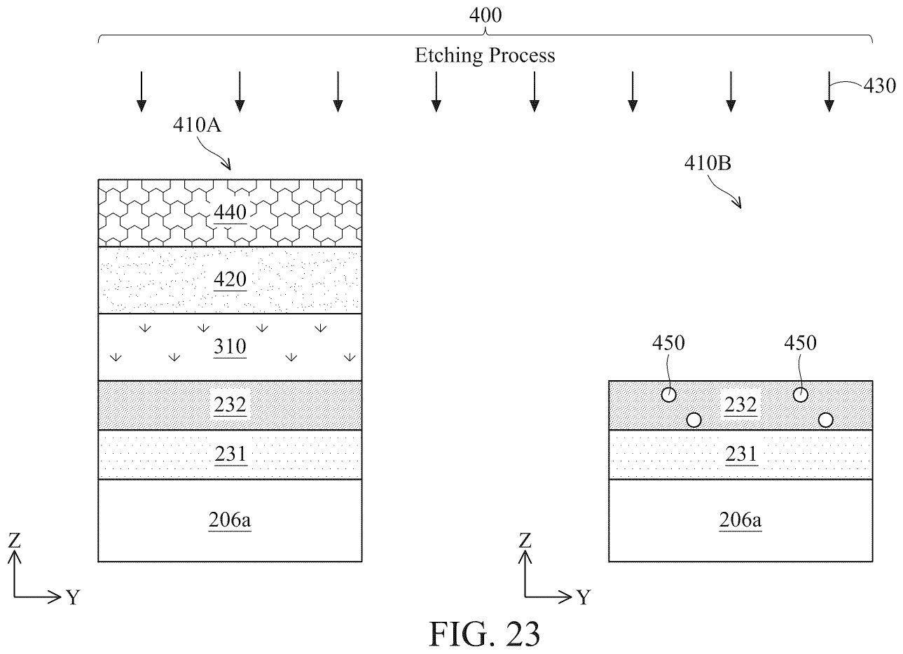

Referring now to FIG. 23, the etching process 430 is performed to the semiconductor structure 400. However, whereas the etching process 430 of FIG. 16 is performed by covering up the stack 410B with the patterning layer 440, the etching process 430 of FIG. 23 is performed by covering the stack 410A with the patterning layer 440, while leaving the stack 410B exposed. Thereafter, the etching process 430 removes the hard mask layer 420 and the dipole layer 310 in the stack 410B, while the patterning layer 440 serves as a protective layer to prevent the hard mask layer 420 (and the layers therebelow) in the stack 410A from being etched.

As a result of the etching process 430, the surfaces of the gate dielectric layer 232 in the stack 410B is exposed. Etchant particles 450 (e.g., which may contain nitrogen or oxygen, as remnants of the etchant of the etching process 430) may be found in the gate dielectric layer 232 of the stack 410B, but not in the gate dielectric layer 232 of the stack 410A, which is the opposite of the embodiment of FIG. 16. This is because the exposed surfaces of the gate dielectric layer 232 of the stack 410B may allow some of the etchant particles 450 to penetrate into the gate dielectric layer 232 of the stack 410B, while the patterning layer 440, the hard mask layer 420, and/or the dipole layer 310 prevents the etchant particles 450 from reaching the gate dielectric layer 232 of the stack 410A. In some embodiments, a concentration of the etchant particles 450 in the gate dielectric layer 232 in the stack 410B may be in a range between about 0.2% and about 4%.

In some embodiments, the etchant particles 450 may even be found in the interfacial layer 231 of the stack 410B. However, since the interfacial layer 231 is located beneath the gate dielectric layer 232, the concentration (or amount) of the etchant particles 450 in the interfacial layer 231 may be lower than the concentration (or amount) of the etchant particles 450 in the gate dielectric layer 232. As discussed above, the presence of the etchant particles 450 in the gate dielectric layer 232 (and possibly in the interfacial layer 231) of the stack 410B (but not in the stack 410A) is one of the inherent results of the unique fabrication process flow being performed herein.

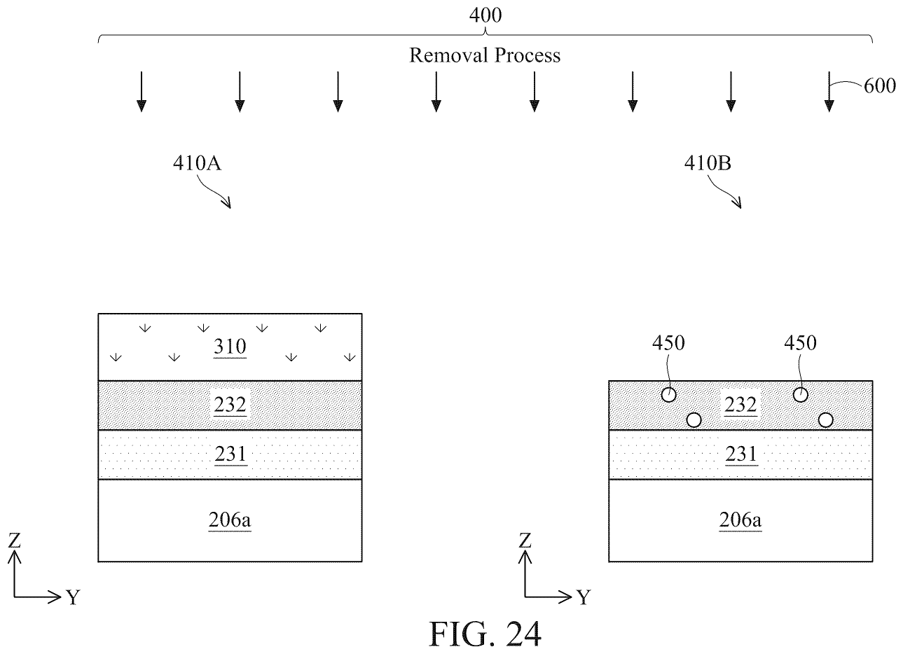

Referring now to FIG. 24, one or more removal processes 600 are performed to the semiconductor structure 400. The one or more removal processes 600 may include a photoresist stripping process or a photoresist ashing process that removes the patterning layer 440. The one or more removal processes 600 may also include one or more etching processes that removes the hard mask layer 420 of the stack 410A. At the end of the one or more removal processes 600, the surfaces of the dipole layer 310 in the stack 410A and the surfaces of the gate dielectric layer 232 in the stack 410B are exposed.

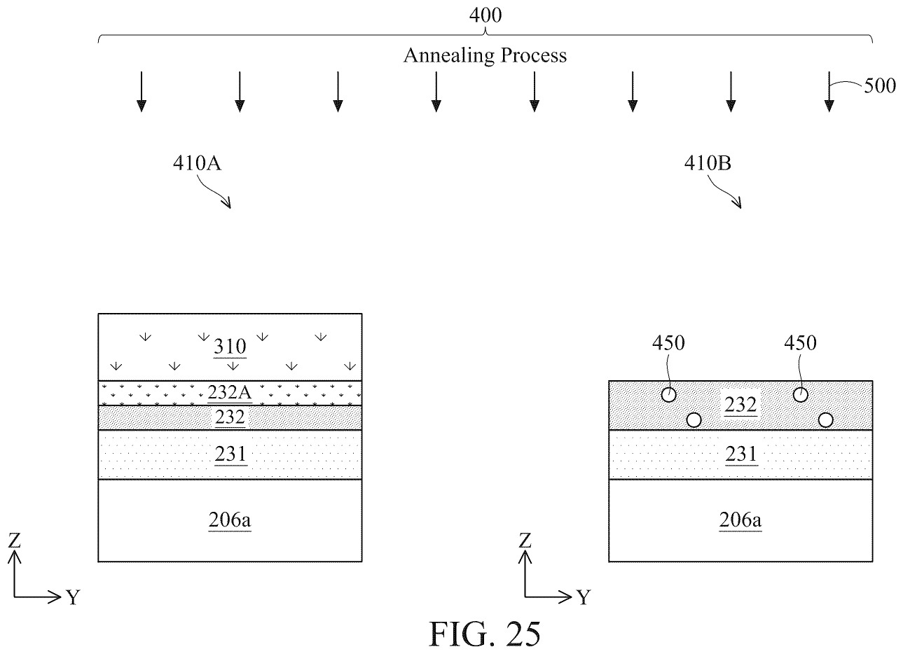

Referring now to FIG. 25, the annealing process 500 is performed to the semiconductor structure 400. As discussed above, the annealing process 500 may be the first step of the annealing process 380 discussed above with reference to FIGS. 13A-13B, and it may be performed at a process temperature in a range between about 500 degrees C. and about 800 degrees C., and with a duration in a range between about 1 second and about 5 minutes. The annealing process 500 helps to facilitate a movement of the dopant atoms from the dipole layer 310 into the gate dielectric layer 232 of the stack 410A. In other words, the annealing process 500 causes a portion of the gate dielectric layer 232A of the stack 410A to intermix with the dipole layer 310 formed thereon. As such, the annealing process 500 may also be referred to as an intermixing process. The result is that the intermixed portion of the gate dielectric layer 232A may become doped with the dopant of the dipole layer 310. In some embodiments, the thickness of the intermixed portion of the gate dielectric layer 232A is in a range between about 10% and about 50% of the depth (or thickness) of the gate dielectric layer 232.

While the annealing process 500 causes the dopants of the dipole layer 310 to penetrate partially into the gate dielectric layer 232 of the stack 410A, the gate dielectric layer 232 of the stack 410B experiences no such dipole intermixing, since no dipole layer is located over the gate dielectric layer 232 of the stack 410B at the time the annealing process 500 is performed. In other words, the selective formation of the dipole layer 310 in the stack 410A but not in the stack 410B allows the gate dielectric layer 232 of the stack 410A to become partially doped with the dipole dopants but prevents the gate dielectric layer 232 of the stack 410B from being doped. At this stage of fabrication, the stack 410A includes a partially doped gate dielectric layer 232 (e.g., the intermixed portion of the gate dielectric layer 232A), while the gate dielectric layer 232 in the stack 410B remains undoped.

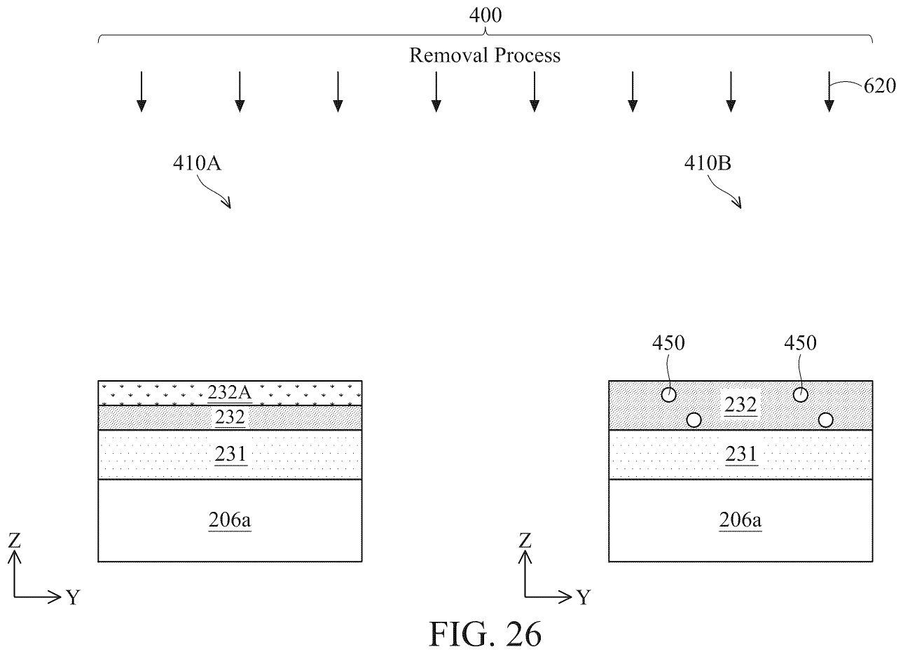

Referring now to FIG. 26, after the annealing process 500 has been performed (leading to the formation of the intermixed portion of the gate dielectric layer 232A in the stack 410A), the dipole layer 310 is removed using one or more removal processes 620. In some embodiments, the removal processes 620 may include one or more etching processes configured to etch away the dipole layer 310.

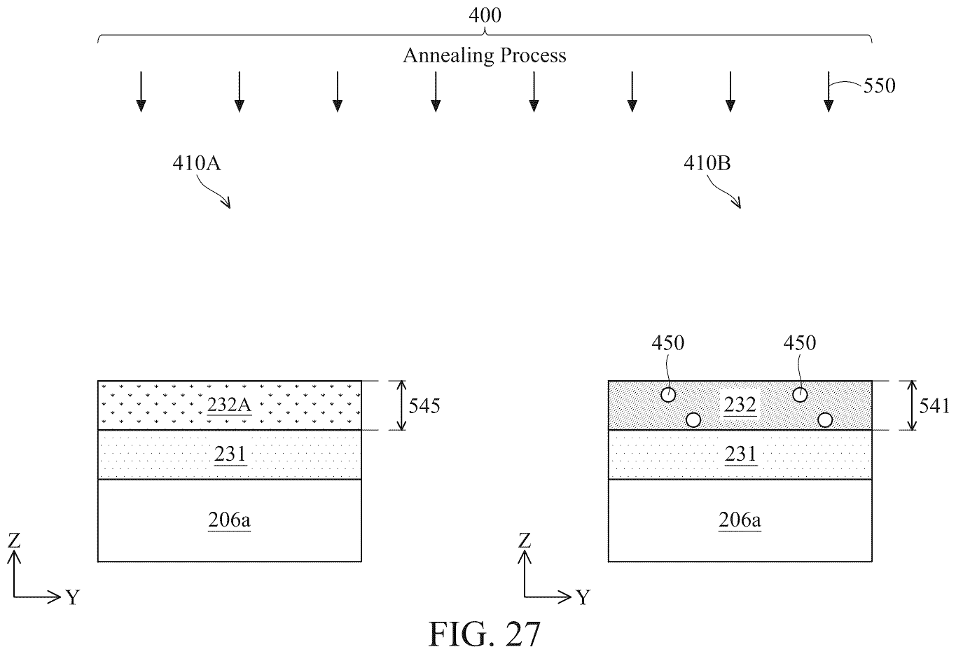

Referring now to FIG. 27, the annealing process 550 is performed to the semiconductor structure 400. The annealing process 550 may be the second step of the annealing process 380 discussed above with reference to FIGS. 13A-13B. As the dipole drive-in process, the annealing process 550 is performed at a greater temperature than the annealing process 500. In some embodiments, the annealing process 550 is performed at a process temperature in a range between about 800 degrees C. and about 1200 degrees C. In some embodiments, the annealing process 550 is performed for a duration in a range between about 1 second and about 5 minutes. In some embodiments, the annealing process 550 includes a spike annealing process. The annealing process 550 further drives the dopant atoms of the intermixed portions of the gate dielectric layer 232A into the rest of the gate dielectric layer 232 of the stack 410A. As a result of the annealing process 550, a substantial entirety of the gate dielectric layer 232A is now doped.

The doped gate dielectric layer 232A has a thickness 545, which may not be substantially different from the thickness 541 of the un-doped gate dielectric layer 232. On the one hand, the etching process 430 (see FIG. 23), the removal process 600, and/or the removal process 620 may lead to a thickness loss for the undoped gate dielectric layer 232 in the stack 410B. On the other hand, the intermixing of the dipole dopants with the gate dielectric layer 232 of the stack 410A to form the doped gate dielectric layer 232A may also lead to a thickness loss for the doped gate dielectric layer 232A. In the end, the thickness 545 of the doped gate dielectric layer 232A may be in a comparable range with the thickness 541 of the undoped gate dielectric layer 232. For example, in some embodiments, any difference between the thickness 545 and the thickness 541 is less than 0.2 angstroms. Meanwhile, the presence of the etchant particles 450 in the undoped gate dielectric layer 232 but not in the doped gate dielectric layer 232A is still a unique physical characteristic of the semiconductor structure 400, as it is an inherent result of the performance of the fabrication processes of FIGS. 22-27.

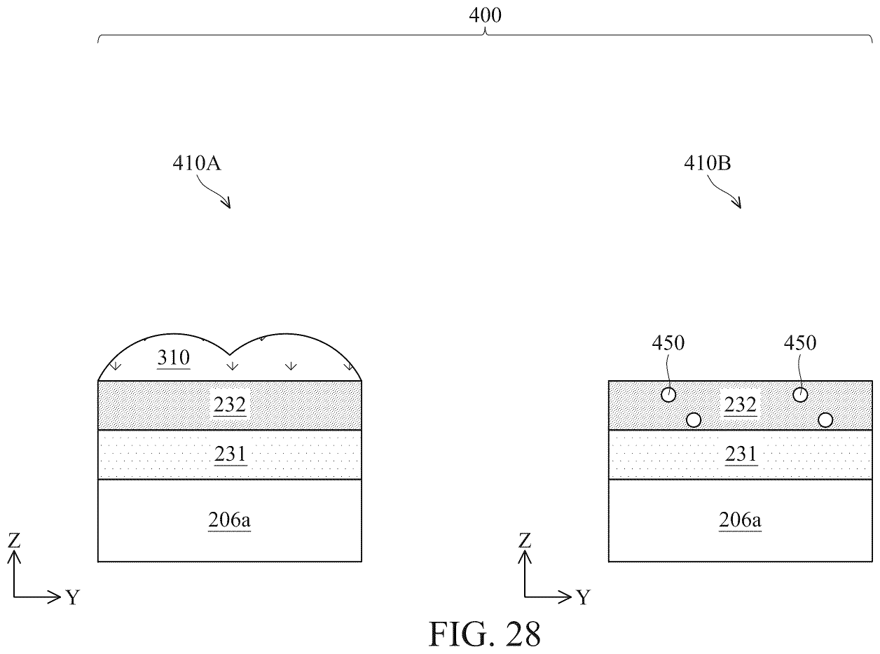

It is understood that although the embodiments discussed above may form a dipole layer 310 that has a relatively uniform thickness, such a uniform thickness of the dipole layer 310 is not required to implement the various aspects of the present disclosure. For example, referring to FIG. 28, a dipole layer 310 having a non-uniform thickness may also be used to implement the present disclosure. In other words, the dopants from the non-uniform dipole layer 310 may still be driven into the gate dielectric layer 232 of the stack 410A via a two-step annealing process discussed above, and as long as the non-uniform dipole layer 310 still has a sufficient thickness to fill the gaps (e.g., the gaps 370 of FIGS. 13A and 14A) in the stack 410A, then the resulting semiconductor structure 400 can still reduce the dipole loading effect and achieve a more uniform distribution of the dipole dopants in the gate dielectric layer 232.

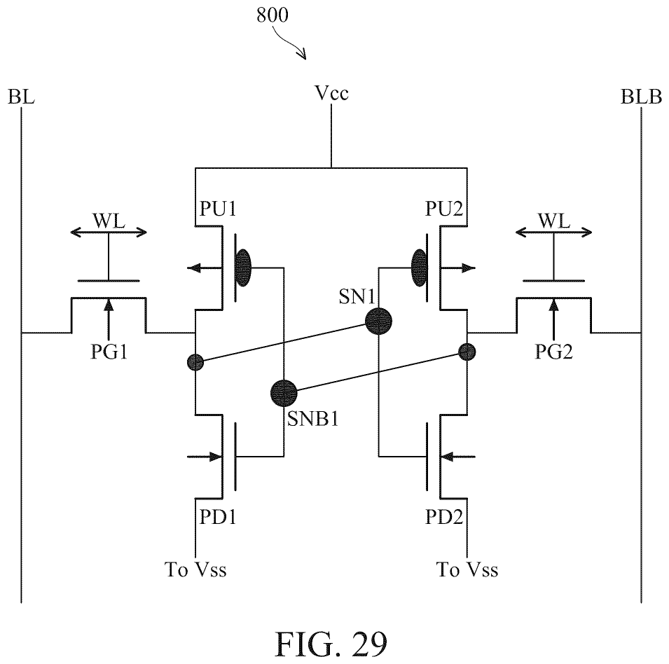

FIG. 29 illustrates an example type of memory device in which the semiconductor structure 200 or the semiconductor structure 400 may be implemented. In that regard, FIG. 29 illustrates the circuit schematic of an example Static Random-Access Memory (SRAM) device, for example, as a single-port SRAM cell (e.g., 1-bit SRAM cell) 800. The single-port SRAM cell 800 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. According to the various aspects of the present disclosure, the PG1, PG2, PD1, and PD2 transistors are implemented with thinner spacers than the PU1 and PU2 transistors. Since the SRAM cell 800 includes six transistors in the illustrated embodiment, it may also be referred to as a 6T SRAM cell. Regardless, the transistor 710A may be used to implement the PG1, PG2, PD1, PD2, PU1, and/or the PU2 transistors.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node SN1 and the complementary first storage node SNB1 are complementary nodes that are often at opposite logic levels (logic high or logic low). Gates of pass-gate transistors PG1 and PG2 are coupled to a word line WL. SRAM devices such as the SRAM cell 800 may be implemented using “planar” transistor devices, with FinFET devices, and/or with GAA devices.

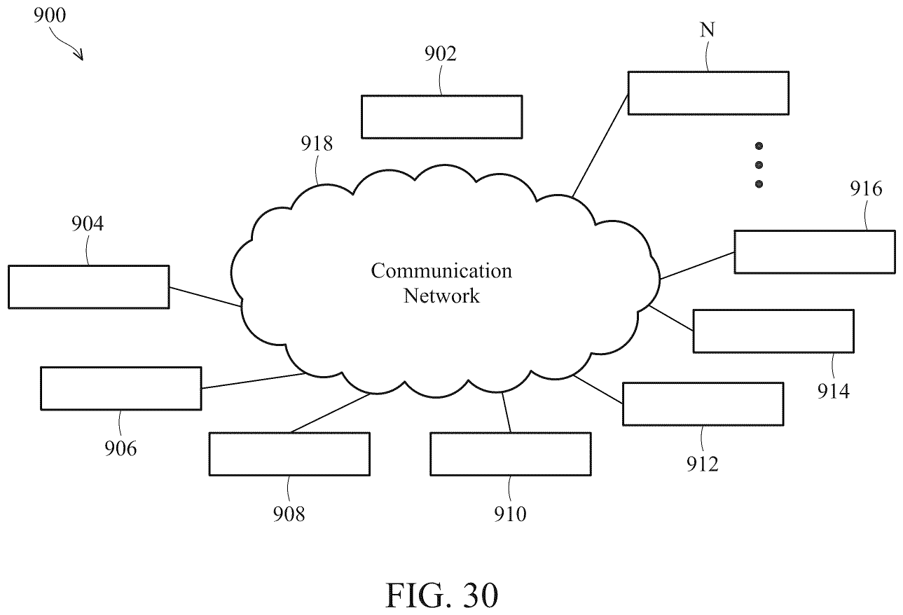

FIG. 30 illustrates an integrated circuit fabrication system 900 that can be used to fabricate the semiconductor structure 200 or the semiconductor structure 400 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the gate spacers of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

In summary, the present disclosure uses unique fabrication processes to form more uniformly doped gate dielectric layers of GAA devices. For example, dipole layers are formed to circumferentially surround a plurality gate dielectric layers in a stack, respectively, where the gate dielectric layers each circumferentially surround a respective nano-structure (e.g., a channel of the GAA device) in the stack. The thickness of the dipole layers are configured to be sufficiently thick so that they will merge into one another to fill the gaps that would otherwise vertically separate the different ones of the gate dielectric layers (along with the nano-structures circumferentially surrounded therein) in the stack. As such, it may be said that a single continuous dipole structure circumferentially surrounds all the gate dielectric layers (and their respective nano-structures) therein. One or more annealing processes, such as a two-step annealing process, may then be performed to drive the dopants of the dipole layer into the gate dielectric layers, thereby forming doped gate dielectric layers.

The present disclosure offers various advantages. However, it is understood that not all advantages are discussed herein, different embodiments may offer different advantages, and that no particular advantage is required for any embodiment. One advantage is improved dopant distribution uniformity in the gate dielectric layer. In more detail, certain types of GAA devices may have nano-structure channels that have square-like cross-sectional profiles or short widths. These types of GAA devices are susceptible to a dipole dopant loading effect, which occurs when the corner regions of the gate dielectric layer have a substantially greater concentration of dipole dopants than a rest of the gate dielectric layer. Here, the present disclosure forms a sufficiently thick dipole layer around the gate dielectric layers, such that the subsequent dipole dopant distribution is not dominated by the corner regions of the dipole layer. Rather, the sufficient thickness of the dipole layer, coupled with carefully configured annealing process parameters, allows the dipole dopants to be driven more uniformly into all portions of the gate dielectric layers. As a result, the dipole dopant loading effect is reduced, and device performance is enhanced. Other advantages may include compatibility with existing fabrication processes and the ease and low cost of implementation.

One aspect of the present disclosure pertains to a method. According to the method, a stack of semiconductor layers is formed. The semiconductor layers are spaced apart from one another in a vertical direction by a plurality of gaps in a cross-sectional side view. A plurality of gate dielectric layers is formed over the semiconductor layers. Each of the gate dielectric layers circumferentially surrounds a respective one of the semiconductor layers, and the gate dielectric layers are still spaced apart from one another in the vertical direction by the gaps in the cross-sectional side view. A dipole layer is formed that circumferentially surrounds each of the gate dielectric layers in the cross-sectional side view. The dipole layer contains dopants. The gaps are filled by different portions of the dipole layer in the cross-sectional side view. One or more annealing processes is performed to drive dopants of the dipole layer into the gate dielectric layers. The dipole layer is then removed.

Another aspect of the present disclosure pertains to a structure. The structure includes a first nano-structure channel. A first gate dielectric layer is disposed over the first nano-structure channel. The first gate dielectric layer is doped and has a first thickness. The structure also includes a second nano-structure channel. A second gate dielectric layer is disposed over the second nano-structure channel. The second gate dielectric layer is undoped and has a second thickness that is greater than the first thickness.

Another aspect of the present disclosure pertains to a structure. The structure includes a first nano-structure channel. A first gate dielectric layer is disposed over the first nano-structure channel. The first gate dielectric layer is doped. The structure also includes a second nano-structure channel. A second gate dielectric layer is disposed over the second nano-structure channel. The second gate dielectric layer is undoped. A presence of an etchant is greater in the second gate dielectric layer than in the first gate dielectric layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack of semiconductor layers, wherein the semiconductor layers are spaced apart from one another in a vertical direction by a plurality of gaps in a cross-sectional side view;
forming a plurality of gate dielectric layers over the semiconductor layers, wherein each of the gate dielectric layers circumferentially surrounds a respective one of the semiconductor layers in the cross-sectional side view, and wherein the gate dielectric layers are still spaced apart from one another in the vertical direction by the plurality of gaps in the cross-sectional side view;
forming a dipole layer that circumferentially surrounds each of the gate dielectric layers in the cross-sectional side view, the dipole layer containing dopants, wherein the gaps are filled by different portions of the dipole layer in the cross-sectional side view;
performing one or more annealing processes, wherein the dopants of the dipole layer are driven into the gate dielectric layers by the one or more annealing processes; and
removing the dipole layer.

2. The method of claim 1, wherein the semiconductor layers are first semiconductor layers, and wherein the method further comprises, before the forming of the plurality of the gate dielectric layers:
forming a plurality of second semiconductor layers that interleave with the first semiconductor layers, wherein the first semiconductor layers and the second semiconductor layers have different material compositions;
replacing the second semiconductor layers with a plurality of sacrificial dielectric layers;
laterally etching the sacrificial dielectric layers;
forming inner spacers on side surfaces of the laterally etched sacrificial dielectric layers; and
replacing the laterally etched sacrificial dielectric layers with a gate structure, wherein the gate structure includes the plurality of the gate dielectric layers.

3. The method of claim 1, wherein the forming the dipole layer comprises depositing a plurality of dipole layer segments on the plurality of gate dielectric layers, respectively, wherein the deposited plurality of dipole layer segments are thick enough to merge into one another vertically to form the dipole layer.

4. The method of claim 1, wherein:
the forming the stack of semiconductor layers comprises a first stack of the semiconductor layers and a second stack of the semiconductor layers;
the forming the plurality of the gate dielectric layers comprises forming a plurality of first gate dielectric layers over the first stack of semiconductor layers and forming a plurality of second gate dielectric layers over the second stack of semiconductor layers; and
the method further comprises:
forming first portions of a mask layer over the first gate dielectric layers and forming second portions of the mask layer over the second gate dielectric layers; and
patterning the mask layer at least in part by removing the first portions of the mask layer, while the second portions of the mask layer remain substantially intact after the first portions of the mask layer have been removed;
wherein the forming the dipole layer comprises forming first portions of the dipole layer on the first gate dielectric layers and forming second portions of the dipole layer on the second portions of the mask layer.

5. The method of claim 4, wherein:
the one or more annealing processes drive dopants of the first portions of the dipole layer into the first gate dielectric layers; and
the second portions of the mask layer prevent dopants of the second portions of the dipole layer from being driven into the second gate dielectric layers.

6. The method of claim 4, wherein:
the removing the dipole layer comprises removing the first portions of the dipole layer and the second portions of the dipole layer; and
the first gate dielectric layers are each thinner than each of the second gate dielectric layers after the removing of the dipole layer.

7. The method of claim 4, wherein:
the first portions of the mask layer are removed at least in part using an etching process with a nitrogen-based etchant or an oxygen-based etchant; and
the etching process causes the nitrogen-based etchant or the oxygen-based etchant to penetrate into the first gate dielectric layers but not into the second gate dielectric layers.

8. The method of claim 4, wherein:
the forming the stack of semiconductor layers comprises a first stack of the semiconductor layers and a second stack of the semiconductor layers;
the forming the plurality of the gate dielectric layers comprises forming a plurality of first gate dielectric layers over the first stack of semiconductor layers and forming a plurality of second gate dielectric layers over the second stack of semiconductor layers; and
the method further comprises:
forming first portions of a mask layer over the first portions of the dipole layer and forming second portions of the mask layer over the second portions of the dipole layer; and
patterning the mask layer and the dipole layer at least in part by removing the second portions of the mask layer and the second portions of the dipole layer, while the first portions of the mask layer and the first portions of the dipole layer remain substantially intact after the second portions of the mask layer and the second portions of the dipole layer have been removed.

9. The method of claim 8, wherein the one or more annealing processes drive dopants of the first portions of the dipole layer into the first gate dielectric layers, and wherein the method further comprises removing the first portions of the mask layer before the dopants of the first portions of the dipole layer have been driven into the first gate dielectric layers.

10. The method of claim 8, wherein:
the second portions of the mask layer are removed at least in part using an etching process with a nitrogen-based etchant or an oxygen-based etchant; and
the etching process causes the nitrogen-based etchant or the oxygen-based etchant to penetrate into the second gate dielectric layers but not into the first gate dielectric layers.

11. The method of claim 1, wherein the performing the one or more annealing processes comprises:
performing a first annealing process with a process temperature in a range between about 500 degrees C. and about 800 degrees C.; and
performing a second annealing process with a process temperature in a range between about 800 degrees C. and about 1200 degrees C.

12. A structure, comprising:
a first nano-structure channel;
a first gate dielectric layer disposed over the first nano-structure channel, wherein the first gate dielectric layer is doped and has a first thickness;
a second nano-structure channel; and
a second gate dielectric layer disposed over the second nano-structure channel, wherein the second gate dielectric layer is undoped and has a second thickness that is greater than the first thickness.

13. The structure of claim 12, wherein a concentration of remnants of an etchant is greater in the first gate dielectric layer than in the second gate dielectric layer.

14. The structure of claim 13, wherein the remnants of the etchant comprise nitrogen or oxygen.

15. The structure of claim 12, wherein a difference between the second thickness and the first thickness is in a range between about 0.2 angstroms and about 2 angstroms.

16. The structure of claim 12, wherein the first nano-structure channel and the second nano-structure channel each have a square-like shape in a cross-sectional side view.

17. A structure, comprising:
a first nano-structure channel;
a first gate dielectric layer disposed over the first nano-structure channel, wherein the first gate dielectric layer is doped;
a second nano-structure channel; and
a second gate dielectric layer disposed over the second nano-structure channel, wherein the second gate dielectric layer is undoped, and wherein a presence of an etchant is greater in the second gate dielectric layer than in the first gate dielectric layer.

18. The structure of claim 17, wherein the etchant comprises nitrogen or oxygen.

19. The structure of claim 17, wherein a difference between a thickness of the first gate dielectric layer and a thickness of the second gate dielectric layer is less than about 0.2 angstroms.

20. The structure of claim 17, further comprising:
a first interfacial layer disposed between the first nano-structure channel and the first gate dielectric layer; and
a second interfacial layer disposed between the second nano-structure channel and the second gate dielectric layer, wherein the second interfacial layer contains the etchant, but the first interfacial layer does not contain the etchant.
